(19) United States
(12) Patent Application Publication
(10) Pub. No.: US 2011/0306195 A1
(43) Pub. Date: Dec. 15, 2011

(54) METHOD OF MANUFACTURING VERTICAL SEMICONDUCTOR DEVICES

(75) Inventors: Jin-Gyun Kim, Yongin-si (KR); Bo-Young Lee, Hwaseong-si (KR); Ki-Hyun Hwang, Seongnam-si (KR); Eunkee Hong, Seongnam-si (KR); Jong-Wan Choi, Suwon-si (KR)

(73) Assignee: SAMSUNG ELECTRONICS CO., LTD., Suwon-si (KR)

(21) Appl. No.: 13/099,485

(22) Filed: May 3, 2011

(30) Foreign Application Priority Data
Jun. 14, 2010 (KR) 10-2010-0056152

(51) Int. Cl. H01L 21/28

(52) U.S. Cl. 438/591; 257/E21.19

(57) ABSTRACT

In a vertical semiconductor device and a method of manufacturing a vertical semiconductor device, sacrificial layers and insulating interlayers are repeatedly and alternately stacked on a substrate. The sacrificial layers include boron (B) and nitrogen (N) and have an etching selectivity with respect to the insulating interlayers. Semiconductor patterns are formed on the substrate through the sacrificial layers and the insulating interlayers. The sacrificial layers and the insulating interlayers are at least partially removed between the semiconductor patterns to form sacrificial layer patterns and insulating interlayer patterns on sidewalls of the semiconductor patterns. The sacrificial layer patterns are removed to form grooves between the insulating interlayer patterns. The grooves expose portions of the sidewalls of the semiconductor patterns. A gate structure is formed in each of the grooves.

### CROSS-REFERENCE TO RELATED APPLICATIONS

This application claims priority under 35 USC §119 to Korean Patent Application No. 10-2010-0056152 filed on Jun. 14, 2010 in the Korean Intellectual Property Office (KIPO), the contents of which are herein incorporated by reference in their entirety.

### BACKGROUND

1. Field

Exemplary embodiments relate to vertical semiconductor devices and methods of manufacturing vertical semiconductor devices. More particularly, exemplary embodiments relate to non-volatile memory devices which include a vertical channel and methods of manufacturing the non-volatile memory devices.

2. Description of the Related Art

Recently, in semiconductor memory devices, it has become increasingly important to improve the integration density or degree of integration of devices. To that end, methods of forming a plurality of transistors in a vertical direction relative to the device substrate have been developed. According to these methods, sacrificial layers and insulation layers are alternately and repeatedly stacked. The sacrificial layers and the insulation layers may be subject to stress, and, therefore, may be bent or cracked, or the layers may be lifted. As a result, these vertical semiconductor devices that include the vertically stacked transistors may have low reliability.

### SUMMARY

Exemplary embodiments provide a vertical semiconductor device having high reliability and a stable structure.

Exemplary embodiments provide a method of manufacturing a vertical semiconductor device having high reliability and a stable structure.

According one aspect, the inventive concept is directed to a method of manufacturing a vertical semiconductor device. According the method, a plurality of sacrificial layers and a plurality of insulating interlayers are formed on a substrate. The sacrificial layers may include boron (B) and nitrogen (N) and may have an etching selectivity with respect to the insulating interlayers. The plurality of sacrificial layers and the plurality of insulating interlayers are repeatedly and alternately stacked on the substrate. Semiconductor patterns may be formed on the substrate through the sacrificial layers and the insulating interlayers. The sacrificial layers and the insulating interlayers may be partially removed between the semiconductor patterns to form sacrificial layer patterns and insulating interlayer patterns on sidewalls of the semiconductor patterns. The sacrificial layer patterns may be removed to form grooves between the insulating interlayer patterns. The grooves may expose portions of the sidewalls of the semiconductor patterns. A gate structure may be formed in each of the grooves.

In some exemplary embodiments, the sacrificial layers may include at least one of BN, c-BN, SiBN, SiBCN, BN containing oxygen or SiBN containing oxygen.

In some exemplary embodiments, the sacrificial layers may be formed using BCl₃ and NH₃ as a source gas under an atmosphere of Ar.

In some exemplary embodiments, an etching rate of the sacrificial layers may be controlled by adjusting a flow rate of BCl₃ in the source gas

In some exemplary embodiments, the source gas for forming the sacrificial layers may further include a silicon source gas.

In some exemplary embodiments, the source gas for forming the sacrificial layers may further include a carbon and/or an oxygen source gas.

In some exemplary embodiments, the sacrificial layers may be deposited at a temperature of about 300 to about 800° C.

In some exemplary embodiments, the sacrificial layers may be formed by at least one of a PECVD process, a thermal CVD process and an ALD process.

In some exemplary embodiments, the insulating interlayers may include at least one of silicon oxide, SiOC and SiOF.

In some exemplary embodiments, the grooves may have a difference between a maximum width and a minimum width that is less than about 10% of the maximum width.

In some exemplary embodiments, in forming the gate structure, a tunnel insulation layer, a charge trapping layer and a blocking layer may be sequentially formed on the exposed portions of the sidewalls of the semiconductor patterns and surfaces of the insulating interlayer patterns. A conductive layer may be formed on the blocking layer to fill the grooves. The conductive layer may be at least partially removed to form gate electrodes in the grooves.

In some exemplary embodiments, the sacrificial layer patterns may be removed using sulfuric acid and/or phosphoric acid.

In some exemplary embodiments, in forming the semiconductor patterns, the sacrificial layers and the insulating interlayers may be at least partially removed to form an opening through the sacrificial layers and the insulating interlayers. The opening may expose a top surface of the substrate. A semiconductor layer may be formed on the exposed top surface of the substrate to fill the opening. A semiconductor pattern in the opening may be formed by planarizing an upper portion of the semiconductor layer.

In some exemplary embodiments, in forming the semiconductor patterns, the sacrificial layers and the insulating interlayers may be partially removed to form an opening through the sacrificial layers and the insulating interlayers. The opening may expose a top surface of the substrate. A semiconductor layer may be formed on the exposed top surface of the substrate and a sidewall of the opening. A filling layer may be formed on the semiconductor layer to fill the opening. A semiconductor pattern and a filling layer pattern may be formed by planarizing upper portions of the filling layer and the semiconductor layer.

In some exemplary embodiments, the insulating interlayer patterns, after removing the sacrificial layer patterns, may have a thickness more than about 95% of an initial thickness of the insulating interlayers.

According to another aspect, the inventive concept is directed to a vertical semiconductor device. In the device, a semiconductor pattern may protrude from a top surface of a substrate. A plurality of insulating interlayer patterns may be disposed on sidewalls of the semiconductor pattern. The insulating interlayer patterns may be spaced apart to define first grooves between the insulating interlayer patterns. A gate structure may be formed in each of the first grooves. The difference between a maximum width and a minimum width of the first grooves may be less than about 10% of the maximum width of the first grooves.

In some exemplary embodiments, the gate structure may have a gate electrode which includes a metal.

In some exemplary embodiments, in the gate structure, a tunnel insulation layer, a charge trapping layer and a blocking layer may be sequentially stacked on the sidewall of the semiconductor pattern and surfaces of the insulating interlayer patterns. The gate electrode may fill each of second grooves. The second grooves are defined by a remaining portion of the first grooves after forming the tunnel insulation layer, the charge trapping layer and the blocking layer.

In some exemplary embodiments, a difference between a maximum width and a minimum width of the second grooves may be less than about 50% of the maximum width of the second grooves.

In some exemplary embodiments, the insulation layer patterns may include at least one of silicon oxide, SiOC and SiOF.

According to another aspect, the inventive concept is directed to a method of manufacturing a vertical semiconductor device, the method comprising: alternately stacking a plurality of sacrificial layers and a plurality of insulating interlayers on a substrate, the plurality of sacrificial layers including boron (B) and nitrogen (N) and having an etching selectivity with respect to the insulating interlayers, the plurality of sacrificial layers being formed using at least one of BCl₃ and NH₃ as a source gas; forming semiconductor patterns on the substrate, the semiconductor patterns being formed through the sacrificial layers and the insulating interlayers; at least partially removing the sacrificial layers and the insulating interlayers between the semiconductor patterns to form sacrificial layer patterns and insulating interlayer patterns on sidewalls of the semiconductor patterns; removing the plurality of sacrificial layer patterns to form a respective plurality of grooves between the insulating interlayer patterns, the plurality of grooves exposing portions of the sidewalls of the semiconductor patterns; and forming a plurality of gate structures in the plurality of grooves, respectively. Forming the plurality of gate structures comprises: sequentially forming a tunnel insulation layer, a charge trapping layer and a blocking layer on the exposed portions of the sidewalls of the semiconductor patterns and surfaces of the insulating interlayer patterns, forming a conductive layer on the blocking layer to fill the grooves, and at least partially removing the conductive layer to form gate electrodes in the grooves.

In some exemplary embodiments, the sacrificial layers are formed in an atmosphere comprising Ar.

In some exemplary embodiments, the sacrificial layers comprise at least one of BN, c-BN, SiBN, SiBCN, BN containing oxygen, and SiBN containing oxygen.

In some exemplary embodiments, the method further comprises adjusting a flow rate of BCl₃ in the source gas to control an etching rate of the plurality of sacrificial layers.

In some exemplary embodiments, the plurality of sacrificial layers is formed using at least one of a PECVD process, a thermal CVD process and an ALD process.

According to exemplary embodiments, in manufacturing the vertical semiconductor device, sacrificial layers and insulating interlayers may be formed using a material or materials that has (have) a low stress or stress change induced by a thermal treatment. Thus, defects in the layers such as lifting, cracking or bending that may occur in the stress are prevented so that electrical characteristics of the device are enhanced. Additionally, insulating interlayer patterns may have an improved surface profile because an etching selectivity between the sacrificial layers and the insulating interlayers is very high. Therefore, an amount of metal that is required to form control gate electrodes in grooves between the insulating interlayer patterns may be reduced so that the entire process cost may also be reduced.

### BRIEF DESCRIPTION OF THE DRAWINGS

The foregoing and other features and advantages of the inventive concept will be apparent from the more particular description of preferred embodiments of the inventive concept, as illustrated in the accompanying drawings in which like reference characters refer to the same parts throughout the different views. The drawings are not necessarily to scale, emphasis instead being placed upon illustrating the principles of the inventive concept. In the drawings, the thickness of layers and regions may be exaggerated for clarity.

FIG. 1 is a schematic circuit diagram illustrating a vertical semiconductor device, in accordance with exemplary embodiments of the inventive concept.

FIG. 2 is a schematic cross-sectional view illustrating a vertical semiconductor device, in accordance with exemplary embodiments of the inventive concept.

FIG. 3A is a schematic perspective view illustrating the vertical semiconductor device of FIG. 2, in accordance with exemplary embodiments of the inventive concept.

FIG. 3B is a schematic perspective view illustrating a portion A of the vertical semiconductor device of FIG. 2, in accordance with exemplary embodiments of the inventive concept.

FIG. 4 is a partially enlarged schematic cross-sectional view illustrating insulating interlayer patterns, in accordance with exemplary embodiments of the inventive concept.

FIGS. 5A to 5I are schematic cross-sectional views illustrating a method of manufacturing the vertical semiconductor device of FIGS. 1 to 3, in accordance with exemplary embodiments of the inventive concept.

FIGS. 6A and 6B are partially enlarged schematic cross-sectional views illustrating insulating interlayer patterns and a second groove, in accordance with exemplary embodiments of the inventive concept.

FIG. 7 is a schematic cross-sectional view illustrating a vertical semiconductor device, in accordance with exemplary embodiments of the inventive concept.

FIG. 8 is a schematic cross-sectional view illustrating a method of manufacturing the vertical semiconductor device of FIG. 7, in accordance with exemplary embodiments of the inventive concept.

FIG. 9 is a schematic cross-sectional view illustrating a vertical semiconductor device, in accordance with exemplary embodiments of the inventive concept.

FIG. 10A is a schematic perspective view illustrating the vertical semiconductor device of FIG. 9, in accordance with exemplary embodiments of the inventive concept.

FIG. 10B is a schematic perspective view illustrating a portion of the vertical semiconductor device of FIG. 9, in accordance with exemplary embodiments of the inventive concept.

FIGS. 11A to 11G are schematic perspective views illustrating a method of manufacturing a vertical semiconductor device, in accordance with exemplary embodiments of the inventive concept.

FIG. 12 is a schematic cross-sectional view illustrating a vertical semiconductor device, in accordance with exemplary embodiments of the inventive concept.

FIGS. 13A to 13E are schematic cross-sectional views illustrating a method of manufacturing the vertical semiconductor device of FIG. 12, in accordance with exemplary embodiments of the inventive concept.

FIG. 14 is a graph showing etching rates of layers with respect to etching solutions.

FIG. 15 is a graph showing etching rates of a SiBN layer.

FIG. 16 contains a schematic block diagram illustrating a memory card including a vertical semiconductor device in accordance with exemplary embodiments, in accordance with exemplary embodiments of the inventive concept.

FIG. 17 contains a schematic block diagram illustrating a system including a vertical semiconductor device, in accordance with exemplary embodiments of the inventive concept.

FIG. 18 contains a schematic block diagram illustrating a portable device including a vertical semiconductor device, in accordance with exemplary embodiments of the inventive concept.

### DETAILED DESCRIPTION OF THE EMBODIMENTS

Various exemplary embodiments will be described more fully hereinafter with reference to the accompanying drawings, in which some exemplary embodiments are shown. The present inventive concept may, however, be embodied in many different forms and should not be construed as limited to the exemplary embodiments described herein. Rather, these exemplary embodiments are provided so that this description will be thorough and complete, and will fully convey the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section described below could be termed a second element, component, region, layer or section without departing from the teachings of the present inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature, and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be described in detail with reference to the accompanying drawings.

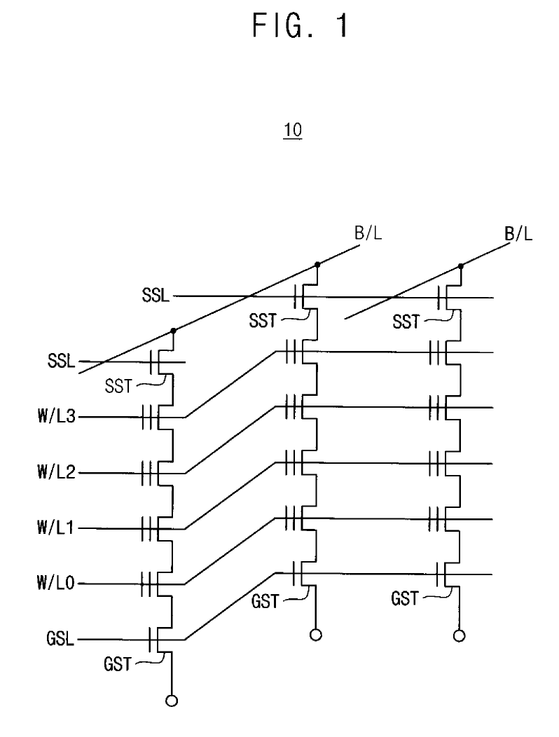

FIG. 1 is a schematic circuit diagram illustrating a vertical semiconductor device in accordance with some exemplary embodiments of the inventive concept. Referring to FIG. 1, a vertical semiconductor device 10 according to the inventive concept may include a plurality of strings. Each string may have a plurality of memory cells stacked in a vertical direction relative to a substrate. Each of the strings may include cell transistors and selection transistors connected in series.

In some exemplary embodiments, each of the cell transistors may include a tunnel insulation layer pattern, a charge trapping layer pattern, a dielectric layer pattern and a control gate electrode. The control gate electrodes of the cell transistors may serve as word lines W/L, illustrated in FIG. 1 as, for example, word lines W/L0 to W/L3. The cell transistors may be connected in series to each other in the vertical direction. In some exemplary embodiments, a ground selection transistor (GST) and a string selection transistor (SST) may be formed at both ends of each string. A control gate electrode of the GST may serve as a ground selection line (GSL). A control gate electrode of the SST may serve as a string selection line (SSL). In some exemplary embodiments, each string may include a plurality of GSTs and a plurality of SSTs connected in series. Additionally, in some exemplary embodiments, a common source line (CSL) may be formed to be connected to the GST. In some exemplary embodiments, the word lines in the same level of the stacked vertical structure may be electrically connected to each other.

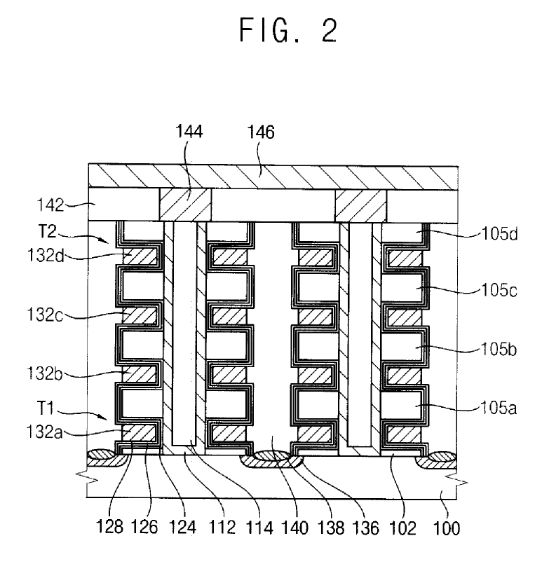

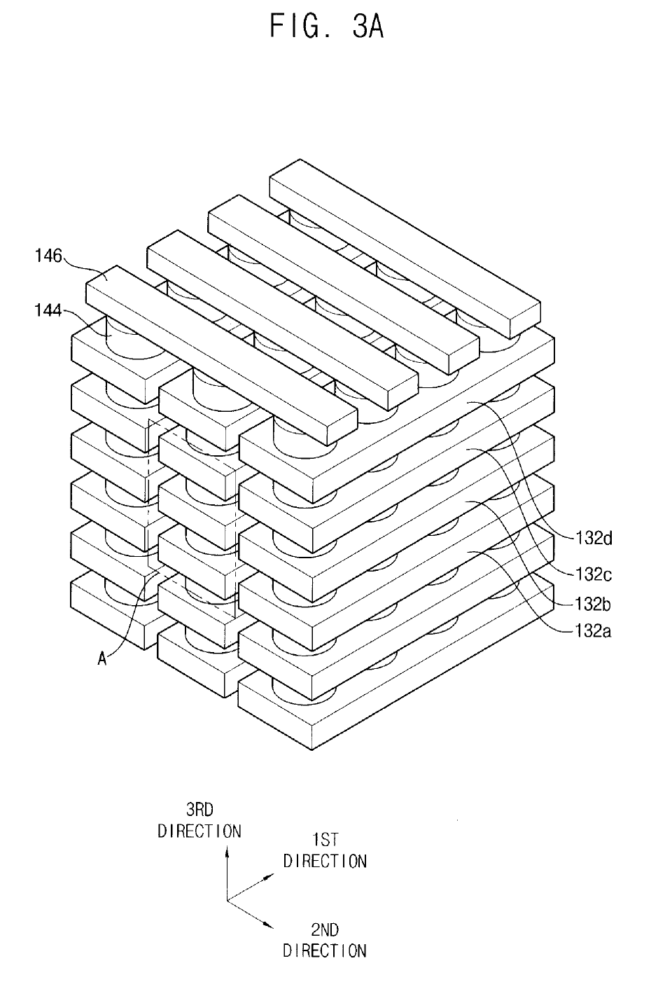

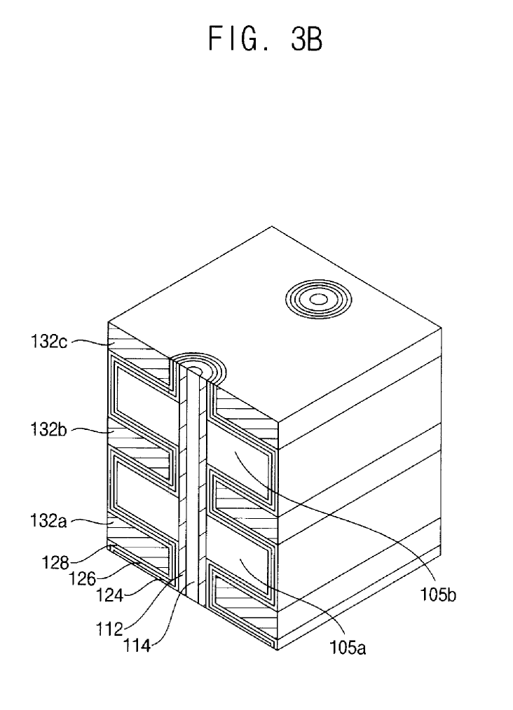

In some exemplary embodiments, the circuit illustrated in FIG. 1 may be realized as shown in FIGS. 2, 3A and 3B. FIG. 2 is a schematic cross-sectional view illustrating a vertical semiconductor device in accordance with some exemplary embodiments. FIG. 3A is a schematic perspective view illustrating the vertical semiconductor device of FIG. 2. FIG. 3B is a schematic perspective view illustrating a portion A of the vertical semiconductor device of FIG. 3A. It should be noted that, hereinafter, a first direction may refer to a direction in which the word line extends, and a second direction may refer to a direction in which a bit line extends throughout the drawings. A third direction may refer to a direction that is vertical with respect to a top surface of the substrate.

In some particular exemplary embodiments according to the inventive concept, a string may include a GST, an SST and two cell transistors between the GST and the SST. In the particular exemplary embodiment illustrated in FIG. 1, each string includes one GST, one SST and four cell transistors between the GST and the SST. However, the string may include different quantities of GSTs, SSTs and/or cell transistors.

Referring to FIGS. 2, 3A and 3B, a semiconductor pattern 112 may be disposed on a substrate 100. In some exemplary embodiments, the semiconductor pattern 112 may include or be made of, for example, single crystalline silicon or polysilicon. In the present exemplary embodiment, the semiconductor pattern 112 may include polysilicon.

As shown in FIGS. 2 and 3B, the semiconductor pattern 112 may have a hollow cylindrical shape or a cup shape, and a bottom of the semiconductor pattern 112 makes contact with a top surface of the substrate 100 and a sidewall in the third direction. The sidewall of the semiconductor pattern 112 may serve as a channel region. In this case, the thickness of the sidewall of the semiconductor pattern 112 serving as a channel region may be decreased so that the operation speed of transistors that include the channel region may be increased. In some exemplary embodiments, the semiconductor pattern 112 may be doped with, for example, p-type impurities. A filling layer pattern 114 may be formed to fill an inner space defined by the bottom and the sidewall of the semiconductor pattern 112.

In some exemplary embodiments, a string may include a plurality of cell transistors which are formed on the sidewall of the semiconductor pattern 112. In some exemplary embodiments, the cell transistors may be connected in series to each other in the third direction. In some exemplary embodiments, a GST and a SST may be disposed at opposite ends of the string. In some particular exemplary embodiments, as illustrated in the figures, a lowermost transistor may serve as the GST T1 and an uppermost transistor may serve as the SST T2. In the particular illustrated embodiment, two cell transistors are shown connected in series between the GST T1 and the SST T2. In exemplary embodiments, the GST T1 and the SST T2 may have a structure substantially the same as or similar to that of the cell transistors, except that a multi-layered structure including a tunnel insulation layer 124, a charge trapping layer 126 and a blocking layer 128 may serve as a gate insulation layer, and control gate electrodes 132a and 132d may serve as a gate electrode.

Insulating interlayer patterns 105a, 105b, 105c and 105d may be disposed in the third direction between cell gate structures of the cell transistors to insulate the cell gate structures from each other. The insulating interlayer patterns 105a, 105b, 105c and 105d may extend in the first direction to at least partially surround the sidewall of the semiconductor pattern 112.

Specifically, in some particular exemplary embodiments, the insulating interlayer patterns 105a, 105b, 105c and 105d may contact an outer sidewall of the semiconductor pattern 112. The insulating interlayer patterns 105a, 105b, 105c and 105d may be disposed to be parallel to one another in each level of the vertically stacked structure and to protrude or extend from the outer sidewall of the semiconductor pattern 112. The insulating interlayer patterns 105a, 105b, 105c and 105d may have, in some exemplary embodiments, a linear shape extending in the first direction. Additionally, the insulating interlayer patterns 105a, 105b, 105c and 105d may be spaced apart from each other in the third direction. As a result, grooves exposing the sidewall of the semiconductor pattern 112 may be formed between the insulating interlayer patterns 105a, 105b, 105c and 105d, and the gate structures may be formed in the grooves, respectively.

In some exemplary embodiments, outer edges of the insulating interlayer patterns 105a, 105b, 105c and 105d may have an almost right angle. That is, the insulating interlayer patterns 105a, 105b, 105c and 105d may have curved areas at their outer edges at which top or bottom surfaces and outer sidewalls of the insulating interlayer patterns 105a, 105b, 105c and 105d meet each other; however, the curved areas may be very short in length. Therefore, the top and bottom surfaces of the insulation interlayer patterns 105a, 105b, 105c and 105d may have planar areas that are not significantly reduced in size by the curved areas.

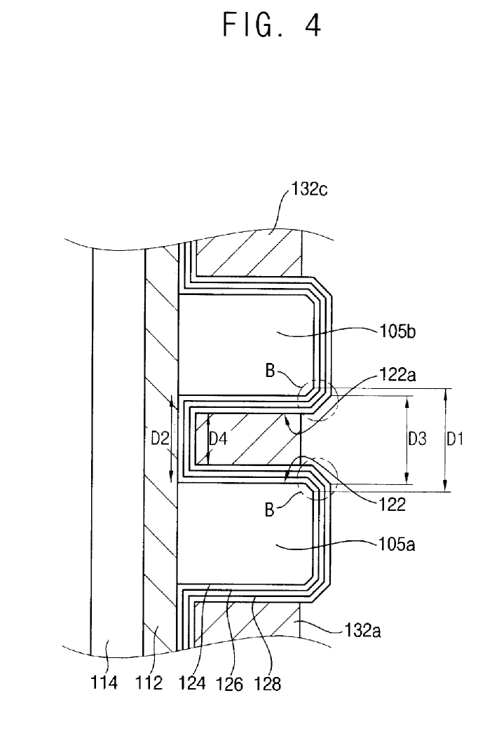

FIG. 4 is a partially enlarged schematic cross-sectional view illustrating the insulating interlayer patterns 105a, 105b, 105c and 105d. Referring to FIG. 4, a first groove 122 may be defined by a space between the adjacent insulating interlayer patterns 105a and 105b. A first width D1 of the first groove 122 is defined by a distance between an uppermost portion of one curved area B of the insulating interlayer patterns 105a, 105b, 105c and 105d and a lowermost portion of another curved area B adjacent thereto. The first width D1 of the first groove 122 may be larger than a second width D2 of the first groove 122 that may be defined by a distance between the adjacent planar areas of the insulating interlayer patterns 105a, 105b, 105c and 105d. However, as noted above, the curved area B may have a very short length, that is, the outer edges of the insulating interlayer patterns 105a, 105b, 105c and 105d may have almost a right angle. As a result, the first groove 122 may have a relatively uniform width regardless of position. In a particular exemplary embodiment, the difference between the first width D1 and the second width D2 may be less than about 10% of the first width D1.

Referring to FIGS. 2 to 3B again, a tunnel insulation layer 124 may be formed on the outer sidewall of the semiconductor pattern 112 exposed by the first groove 122. The tunnel insulation layer 124 may be formed on the outer sidewall of the semiconductor pattern 112 and surfaces of the insulating interlayer patterns 105a, 105b, 105c and 105d. In some exemplary embodiments, as shown in FIG. 3B, the tunnel insulation layer 124 may be formed continuously on the outer sidewall of the semiconductor pattern 112 and the surfaces of the insulating interlayer patterns 105a, 105b, 105c and 105d throughout all levels of the vertically stacked structure. Alternatively, in some exemplary embodiments, a plurality of tunnel insulation layers 124 separated from each other according to the levels of the vertically stacked structure may be formed.

In some exemplary embodiments, a charge trapping layer 126 may be formed on the tunnel insulation layer 124. In some exemplary embodiments, the charge trapping layer 126 may include, for example, silicon nitride or a metal oxide in which electrons may be trapped. Like the tunnel insulation layer 124, the charge trapping layer 126 may be formed continuously throughout all the levels or may separated from each other according to the levels.

A blocking layer 128 may be formed on the charge trapping layer 126. In some exemplary embodiments, the blocking layer 128 may include, for example, silicon oxide or a metal oxide. The metal oxide may include, for example, aluminum oxide.

Referring to FIG. 4 again, a second groove 122a may be defined by top and bottom portions of the blocking layer 128 in the adjacent levels and a vertical portion of the blocking layer 128 between the top and bottom portions. In some exemplary embodiments, the second groove 122a may have a width narrower than that of the first groove 122. A third width D3 is defined by a distance between an uppermost portion of one curved area B of the blocking layer 128 and a lowermost portion of another curved area B adjacent to the uppermost portion. A fourth width D4 is defined by a distance between the adjacent planar areas of the blocking layer 128. In some particular exemplary embodiments, a difference between the widths D3 and D4 may be less than about 50% of the third width D3.

Referring to FIGS. 2 to 3B again, control gate electrodes 132a, 132b, 132c and 132d, which may be separated from each other according the levels of the vertically stacked structure, may be formed on the blocking layer 128. In some exemplary embodiments, the control gate electrodes 132a, 132b, 132c and 132d may serve as word lines W/L. The control gate electrodes 132a, 132b, 132c and 132d in the same level of the vertical structure may be electrically connected to each other by plugs.

In some exemplary embodiments, the control gate electrodes 132a, 132b, 132c and 132d filling the second groove 122a may have a linear shape extending in the first direction. The control gate electrodes 132a, 132b, 132c and 132d may at least partially surround the semiconductor pattern 112. In some exemplary embodiments, the control gate electrodes in different levels may not be electrically connected to each other. The control gate electrodes 132a, 132b, 132c and 132d may include, for example, a metal having a low resistance. As a result, the control gate electrodes 132a, 132b, 132c and 132d may have a reduced thickness, such that the vertical semiconductor device may have a decreased height.

A first insulation layer pattern 140 may be disposed in a gap between adjacent multiple or multi-stacked structures, in which the control gate electrodes 132a, 132b, 132c and 132d and the insulating interlayer patterns 105a, 105b, 105c and 105d are alternately stacked. In some exemplary embodiments, the first insulation layer pattern 140 may extend in the first direction. Additionally, in some exemplary embodiments, a plurality of first insulation patterns 140 may be disposed in the second direction.

In some exemplary embodiments, an impurity region 136 may be formed at an upper portion of the substrate 100 under the first insulation layer pattern 140. In some exemplary embodiments, the impurity region 136 may serve as a common source line (CSL). For example, in some exemplary embodiments, the impurity region 136 may be doped with n-type impurities. A metal silicide pattern 138 may be further formed on the impurity region 136.

An upper insulating interlayer 142 may be formed on the semiconductor pattern 112, the filling layer pattern 114, the first insulation layer pattern 140 and the insulating interlayer pattern 105d. A bit line contact 144 may be formed through the upper insulating interlayer 142 to be electrically connected to the semiconductor pattern 112. A bit line B/L 146 may be formed on the upper insulating interlayer 142 to make contact with the bit line contact 146. In some exemplary embodiments, the bit line 143 may have a linear shape extending in the second direction.

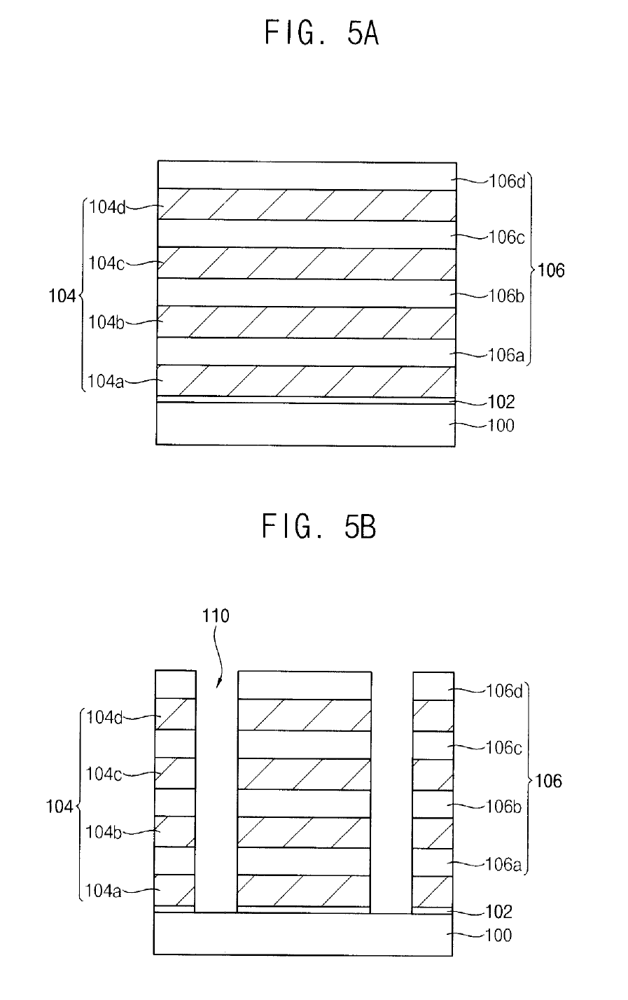

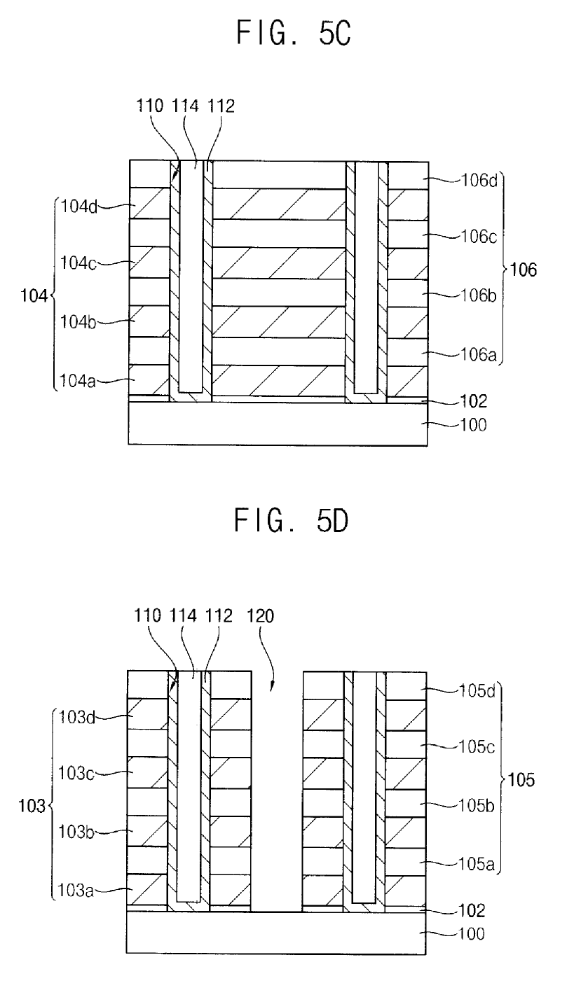

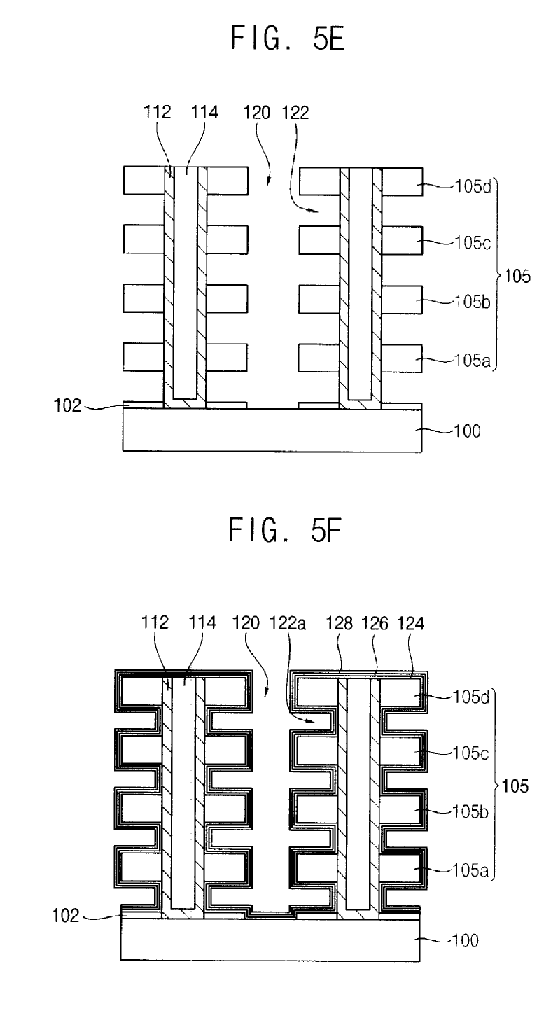

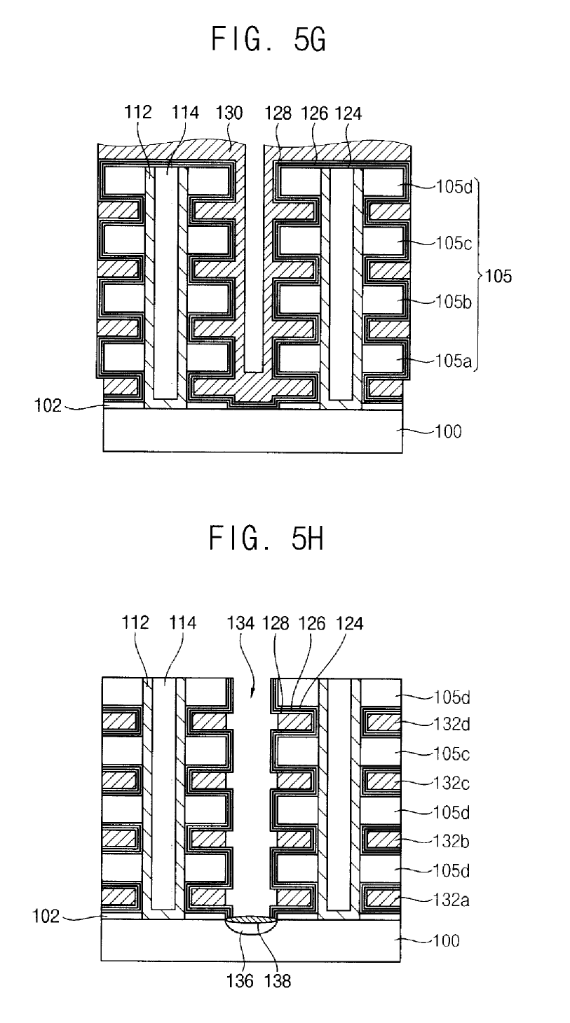

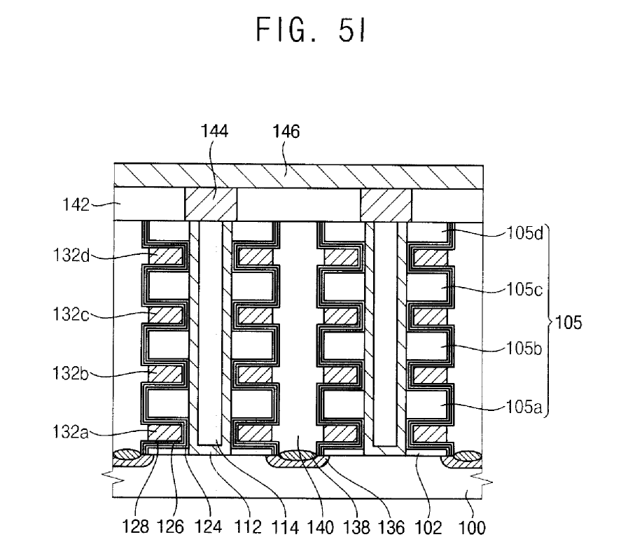

FIGS. 5A to 5I are schematic cross-sectional views illustrating a method of manufacturing the vertical semiconductor device of FIG. 2, according to some exemplary embodiments of the inventive concept.

Referring to FIG. 5A, according to some exemplary embodiments, a pad insulation layer 102 may be formed on a substrate 100. The pad insulation layer 102 may be formed, for example, by a thermal oxidation process. The pad insulation layer 102 may reduce stress that may be generated if sacrificial layers 104 were to be formed directly on the substrate 100. The sacrificial layers 104 and insulating interlayers 106 may be repeatedly and alternately formed on the pad insulation layer 102 in a direction vertical to a top surface of the substrate 100. That is, a first sacrificial layer 104a may be formed on the pad insulation layer 102, and the first insulating interlayer 106a be formed on the first sacrificial layer 104a. Likewise, other sacrificial layers 104b, 104c and 104d and insulating interlayers 106b, 106c and 106d may be sequentially and alternately formed on each other. In some exemplary embodiments, the sacrificial layers 104 and the insulating interlayers 106 may be formed by, for example, a chemical vapor deposition (CVD) process.

In some exemplary embodiments, the sacrificial layers 104 may be formed using a material that may have an etching selectivity with respect to the insulating interlayers 106. In an exemplary embodiment, the etching selectivity between the insulating interlayers 106 and the sacrificial layers 104 may be equal to or greater than about 1:80. In some exemplary embodiments, the sacrificial layers 104 may also have an etching selectivity with respect to a semiconductor pattern 112. That is, the sacrificial layers 104 may be formed using a material that may have an etching selectivity to polysilicon. In an exemplary embodiment, the etching selectivity between polysilicon and the sacrificial layers 104 may be equal to or greater than about 1:80.

The sacrificial layers 104 may be rapidly removed by a wet etching process so that the insulating interlayers 106 may be exposed to a wet etching solution during a very short time period. As a result, the insulating interlayers 106 may be prevented from being damaged by the wet etching solution while the sacrificial layers 104 are removed by the wet etching process.

In some exemplary embodiments, the insulating interlayers 106 may be formed using, for example, silicon oxide (SiO₂). In other exemplary embodiments, the insulating interlayers 106 may be formed using, for example, SiOC or SiOF. As a result, the insulating interlayers 106 may be doped with impurities, e.g., carbon or fluorine, so that the etching selectivity with respect to the sacrificial layers 104 may be adjusted.

In some exemplary embodiments, the sacrificial layers 104 may be formed using a material that may include boron (B) and nitrogen (N). For example, the sacrificial layers 104 may be formed using BN, SiBN, c-BN, c-SiBN, BN including oxygen (O), SiBN including oxygen, or other similar material. In a particular exemplary embodiment, the sacrificial layers 104 including the material may have an etching selectivity with respect to silicon oxide equal to or greater than about 80:1.

A silicon nitride (SiN) layer, which may serve as a sacrificial layer in a semiconductor manufacturing process, may have a high stress during a deposition process or a heat treatment subsequently performed thereon. Accordingly, if a silicon nitride layer is used as a sacrificial layer, the sacrificial layer may have an increased stress while a plurality of silicon nitride layers and a plurality of insulating interlayers are repeatedly formed. Therefore, a multi-layered structure including the sacrificial layers and the insulating interlayers may be bent or cracked, or the multi-layered structure may be lifted

Thus, according to exemplary embodiments of the inventive concept, the sacrificial layers 104 may be formed using a material having a stress or a stress change by a heat treatment smaller than that of a SiN layer. In exemplary embodiments, the sacrificial layers 104 may be formed using the above material including boron and nitrogen, thereby having a stress lower than that of a SiN layer during a deposition process and/or having little stress change by a heat treatment. Thus, even though the sacrificial layers 104 and the insulating interlayers 106 may be repeatedly deposited to form the multi-layered structure having a large height, bending or cracking of the structure are substantially eliminated. Additionally, lifting of the multi-layered structure is eliminated. Furthermore, the hysteresis of the sacrificial layers 104 may not be affected by a thermal stress.

In some exemplary embodiments, the sacrificial layers 104 may be formed by, for example, a plasma enhanced CVD (PECVD) process, a thermal CVD process or an atomic layer deposition (ALD) process.

When a BN layer is formed as the sacrificial layers 104, in some exemplary embodiments, a source gas including BCl₃ and NH₃ may be used under an atmosphere of Ar.

When a SiBN layer is formed as the sacrificial layers 104, in some exemplary embodiments, the source gas may further include a silicon source gas such as, for example, SiH₄, SiH₂Cl₂, SiCl₆, etc. These may be used alone or in a mixture thereof.

When a BCN layer is formed as the sacrificial layers 104, in some exemplary embodiments, a carbon source gas, e.g., C₂H₄, may be further included in the source gas.

When a Si—BCN layer is formed as the sacrificial layers 104, in some exemplary embodiments, the silicon source gas and a carbon source gas may be further included in the source gas.

In some exemplary embodiments, an oxygen gas, that is, a gas including oxygen, such as N₂O, may be further provided during a process for forming the BN layer.

In some exemplary embodiments, oxygen gas such as N₂O may be also provided during a process for forming the SiBN layer.

In some exemplary embodiments, transparency, refractive index, etching rate and other mechanical or structural properties of the sacrificial layers 104 may be adjusted by changing a content of boron included therein. For example, as the content of boron increases, the refractive index may be decreased, and the etching rate for etching solutions including sulfuric acid or phosphoric acid may be increased. Therefore, the etching rate of the sacrificial layers 104 may be controlled by adjusting a flow rate of BCl₃ in the source gas.

In some exemplary embodiments, a transistor may be formed in a space from which the sacrificial layer 106 may be removed. Therefore, the number of sacrificial layers 106 may be greater than or equal to the number of transistors of a string including cell transistors and selection transistors.

Referring to FIG. 5B, an etching mask may be formed on the uppermost insulating interlayer 106d. The insulating interlayers 106, the sacrificial layers 104 and the pad insulation layer 102 may be at least partially removed using the etching mask to form a first opening 110 that may expose a top surface of the substrate 100.

A plurality of first openings 110 may be formed in a regular pattern in the first and second directions. In some exemplary embodiments, the first openings 110 may be formed to have an island shape.

Referring to FIG. 5C, the semiconductor pattern 112 may be formed on a bottom and a sidewall of the first opening 110. Additionally, in some exemplary embodiments, a filling layer pattern 114 may be formed on the semiconductor pattern 112 to fill an inner space of the first opening 110.

In some exemplary embodiments, the semiconductor pattern 112 may have a hollow cylindrical shape or a cup shape. In some exemplary embodiments, the semiconductor pattern 112 may be formed using, for example, single crystalline silicon or polysilicon. The semiconductor pattern 112 may serve as a channel region for a string that may extend in the third direction.

In an exemplary embodiment, a polysilicon layer may be formed conformally on the bottom and the sidewall of the first opening 110. A filling layer may be formed on the polysilicon layer to fill the first opening 110, and a planarization process may be performed on the filling layer and the polysilicon layer to form the semiconductor pattern 112 and the filling layer pattern 114.

In another exemplary embodiment, a polysilicon layer or an amorphous silicon layer may be formed on the bottom and the sidewall of the first opening 110, and then the phase of the polysilicon layer or the amorphous silicon layer may be changed to form a single crystalline silicon layer by, for example, heat treatment or laser irradiation. A planarization process may be performed on the single crystalline silicon layer to form the semiconductor pattern 112.

Referring to 5D, in some exemplary embodiments, the sacrificial layers 104 and the insulating interlayers 106 between the semiconductor patterns 112 may be partially etched to form a second opening 120. Specifically, an etching mask may be formed on the uppermost insulating interlayer 106d, and the insulating interlayers 106 and the sacrificial layers 104 may be partially removed by an etching process using the etching mask to form the second opening 120. In some exemplary embodiments, the second opening 120 may be formed to extend in the first direction. Accordingly, sacrificial layer patterns 103 and insulating interlayer patterns 105 may be formed to have a linear shape extending in the first direction. In some exemplary embodiments, the sacrificial layer patterns 103 and the insulating interlayer patterns 105 may at least partially surround outer sidewalls of the semiconductor patterns 112.

Referring to 5E, the sacrificial layer patterns 103 exposed by the second opening 120 may be removed by a wet etching process. In some exemplary embodiments, the wet etching process may be performed using, for example, sulfuric acid or phosphoric acid when the sacrificial layer patterns 103 may include boron or nitrogen.

In some exemplary embodiments, the sacrificial layer patterns 103 may have an improved etching rate for sulfuric acid or phosphoric acid because of boron and nitrogen included in the sacrificial layer patterns. As a result, the sacrificial layer patterns 103 may be removed rapidly during the exposure to the etching solution even in a very short period. Therefore, damage and/or partial removal of the insulating interlayer patterns 105 during the wet etching process are prevented. A first groove 122 may be defined by a space from which the sacrificial layer patterns 103 are removed.

When sacrificial layer patterns include SiN, a wet etching process for removing the sacrificial layer patterns may be performed for a relatively long time, and, as a result, the insulating interlayer patterns 105 may be also partially removed, such that outer edges of the insulating interlayer patterns 105 that do not contact the semiconductor pattern 112 may have curved areas, which may be relatively large.

However, the sacrificial layer patterns 105 that include boron (B) and nitrogen (N) may be removed very rapidly by the wet etching process, and, as a result, the outer edges of the insulating interlayer patterns 105 may only be removed slightly or not at all. As a result, the curved areas may be relatively small, and the outer edges of the insulating interlayer patterns 105 may have almost a right angle. Accordingly, the first groove 122 may have a relatively uniform width regardless of the position. In an exemplary embodiment, a difference between the largest width and the smallest width of the first groove 122 depending on the position thereof may be less than about 10% of the largest width.

Additionally, the insulating interlayer patterns 105 may be only slightly removed during the removal of the sacrificial layer patterns 103, such that the insulating interlayer patterns 105 may have almost constant thickness even after the wet etching process. In an exemplary embodiment, the insulating interlayer patterns 105 may have a thickness more than about 95% of an initial thickness of the insulating interlayers 106.

Furthermore, the substrate 100 exposed by the second opening 120 may be prevented from being damaged during the wet etching process. In some exemplary embodiments, the wet etching process for removing the sacrificial layer patterns 103 may be performed for a very short time so that the substrate 100 may be exposed to the etching solution for a very short time. Similarly, the semiconductor pattern 112 exposed by the first groove 122 may also be prevented from being damaged by the wet etching process.

Referring to FIG. 5F, a tunnel insulation layer 124 may be formed on outer sidewalls of the semiconductor pattern 112 exposed by the first groove 122 and the insulating interlayer patterns 105. In some exemplary embodiments, the tunnel insulation layer 124 may be formed using, for example, silicon oxide. Alternatively, the tunnel insulation layer 124 may be formed only on the exposed sidewalls of the semiconductor pattern 112 by a thermal oxidation process.

In some exemplary embodiments, a charge trapping layer 126 may be formed on the tunnel insulation layer 124. The charge trapping layer 126 may be formed by, for example, a CVD process using, for example, silicon oxidize or silicon nitride. In some exemplary embodiments, the charge trapping layer 126 may be formed continuously on the tunnel oxide layer.

In some exemplary embodiments, a blocking layer 128 may be formed on the charge trapping layer 126. The blocking layer may 128 be formed by a deposition process using, for example, silicon oxide, a metal oxide such as aluminum oxide, or other similar material. In some exemplary embodiments, the blocking layer 128 may be formed continuously on the charge trapping layer 126.

Hereinafter, a space defined by top and bottom portions of the blocking layer 128 in adjacent levels and a portion therebetween may be referred to as a second groove 122a.

Referring to FIG. 5G a conductive layer 130 may be formed on the blocking layer 128 to sufficiently fill the second groove 122a. In some exemplary embodiments, the conductive layer 130 may be formed to partially fill the second opening 120 such that it can be easily removed by a subsequent process.

In some exemplary embodiments, the conductive layer 130 may be formed using a conductive material having good step coverage. The conductive material may include, for example, a metal or a metal nitride having a low resistance. For example, the conductive material may include tungsten, tungsten nitride, titanium, titanium nitride, tantalum, tantalum nitride or platinum. In an exemplary embodiment, a barrier metal layer including, for example, titanium, titanium nitride, tantalum or tantalum nitride may be formed, and then a metal layer including, for example, tungsten, may be formed thereon.

In some exemplary embodiments, the curved area at the outer edge of the insulating interlayer pattern 105 may have a very small size. As a result, the second groove 122a may have a maximum width that may be slightly larger than a minimum width in the third direction. Accordingly, an amount of the conductive material for filling the second groove 122a may be reduced.

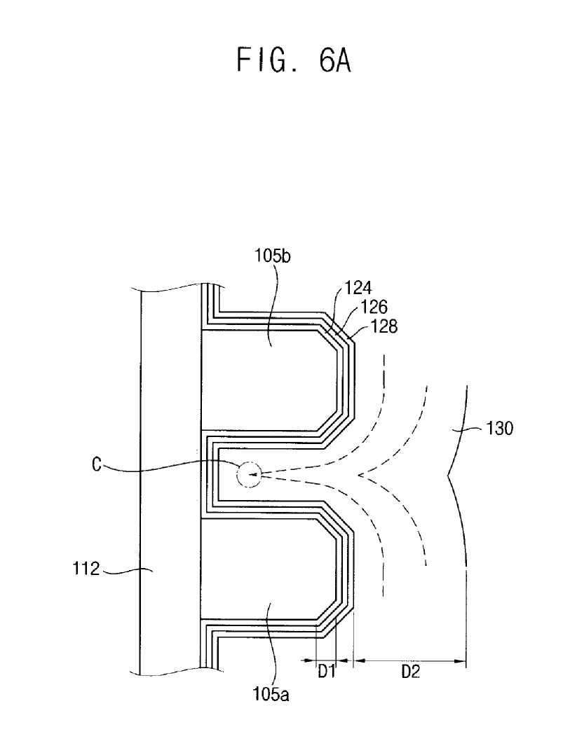

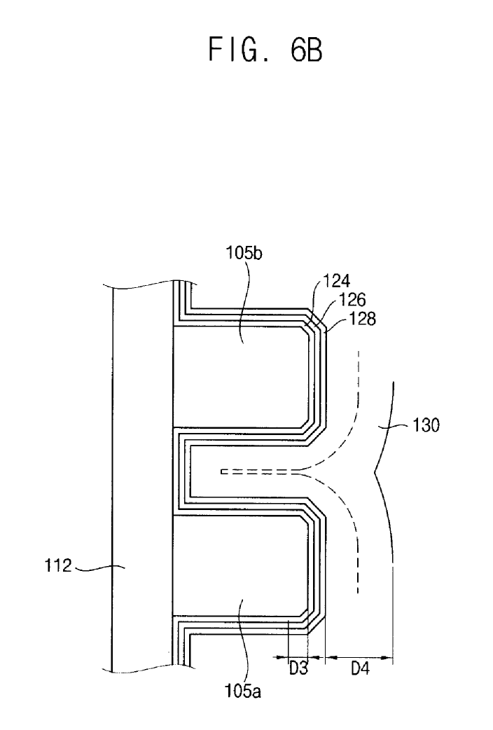

FIGS. 6A and 6B are partially enlarged schematic cross-sectional views illustrating the insulating interlayer patterns 105 and the second groove 122a, according to some exemplary embodiments of the inventive concept. FIG. 6A illustrates the insulating interlayer patterns 105 including large curved areas. A thickness of the curved areas of the insulating interlayer patterns 105 along the second direction is represented by “D1.”

Referring to FIG. 6A, the conductive layer may include a sharp valley C at a center of the second groove 122a, such that additional conductive material may be required to fill the valley C. Accordingly, a thickness D2 of the conductive layer 130 deposited on the blocking layer 128 may be increased.

FIG. 6B illustrates the insulating interlayer patterns 105 including small curved areas according to some exemplary embodiments. A thickness of the curved areas of the insulating interlayer patterns 105 along the second direction is represented by “D3.”

Referring to FIG. 6B, in contrast to FIG. 6A, a sharp valley may not be formed at the center of the second groove 122a. Specifically, conductive layers may be formed on a bottom surface of the insulating interlayer pattern 105b and a top surface of the insulating interlayer pattern 105a, and may make contact with each other uniformly regardless of the position to fill the second groove 122a. As a result, additional conductive material to fill a valley is not required, and a thickness D4 of the conductive layer 130 deposited on the blocking layer 128 may be decreased.

If the thickness of the conductive layer 130 is increased, the process cost may be increased. Also, a relatively thick conductive layer 130 may not be easily removed by a subsequent process. However, according to embodiments of the inventive concept, the insulating interlayer patterns 105 may have small curved areas and small thickness, such that the process cost and the process defects may be reduced.

Referring to FIG. 5H, in some exemplary embodiments, a portion of the conductive layer 130 formed in the second opening 120 may be removed. As a result, the conductive layer 130 may remain only in the second groove 112a to form control gate electrodes 132a, 132b, 132c and 132d. In some exemplary embodiments, portions of the tunnel insulation layer 124, the charge trapping layer 126 and the blocking layer 128 formed on a bottom of the second opening 120 may be also removed by, e.g., a wet etching process, to form a third opening 134.

As described above, in some exemplary embodiments, the conductive layer 130 may be easily removed because the deposition thickness thereof may not be very large.

The control gate electrodes 132a, 132b, 132c and 132d may be formed in the second grooves 112a to be spaced apart from each other and stacked in the third direction. The control gate electrodes 132a, 132b, 132c and 132d in different levels of the stacked structure may be insulated from each other by the insulating interlayer patterns 105a, 105b, 105c and 105d. Each of the control gate electrodes 132a, 132b, 132c and 132d may have a linear shape extending in the first direction.

In some exemplary embodiments, the conductive layer 130 may be partially removed by a dry or a wet etching process.

As shown in FIG. 5H, according to some exemplary embodiments, portions of the tunnel insulation layer 124, the charge trapping layer 126, and/or the blocking layer 128 on the outer sidewalls of the insulating interlayer patterns 105a, 105b, 105c and 105d may not be etched.

Alternatively, according to some exemplary embodiments, in the etching process, the portions of the blocking layer 128 and the charge-trapping layer 126 and/or the tunnel insulation layer 124 on the outer sidewalls of the insulating interlayer patterns 105a, 105b, 105c and 105d may be etched together with the conductive layer 130. In this case, the tunnel oxide layer 124, the charge-trapping layer 126 and/or the blocking layer 128 in different levels of the stacked vertical structure may be separated from each other.

Next, an upper portion of the substrate 100 exposed by the third opening 134 may be doped with impurities, for example, n-type impurities, to form an impurity region 136 serving as a CSL. In some exemplary embodiments, a metal silicide pattern 138 may be further formed on the impurity region 136 in order to reduce resistance of the CSL.

By performing the above steps and processes, transistors of the vertical semiconductor device according to exemplary embodiments of the inventive concept may be formed. An uppermost and a lowermost of the transistors may serve as an SST and a GST, respectively.

Referring to FIG. 5I, in some exemplary embodiments, an insulation layer may be formed on the substrate 100 to fill the third opening 134. The insulation layer may be planarized until the uppermost insulating interlayer pattern 105d is exposed to form a first insulation layer pattern 140 in the third opening 134. An upper insulating interlayer 142 may be formed on top surfaces of the semiconductor pattern 112, the filling layer pattern 114, the first insulation layer pattern 140 and the uppermost insulating interlayer pattern 105d. In some exemplary embodiments, a bit line contact 144 may be formed through the upper insulating interlayer 142 to contact the top surface of the semiconductor pattern 112. A bit line 146 may be formed on the upper insulating interlayer 142 to contact the bit line contact 144. In some exemplary embodiments, the bit line 146 may have a linear shape extending in the second direction and may be electrically connected to the semiconductor pattern 112 via the bit line contact 144.

As described above, in accordance with exemplary embodiments, defects in the process for manufacturing the vertical semiconductor device due to the stress of the sacrificial layers 104 are reduced. Additionally, the insulating interlayers 106 are formed to have an improved surface profile so that the vertical semiconductor device has high reliability.

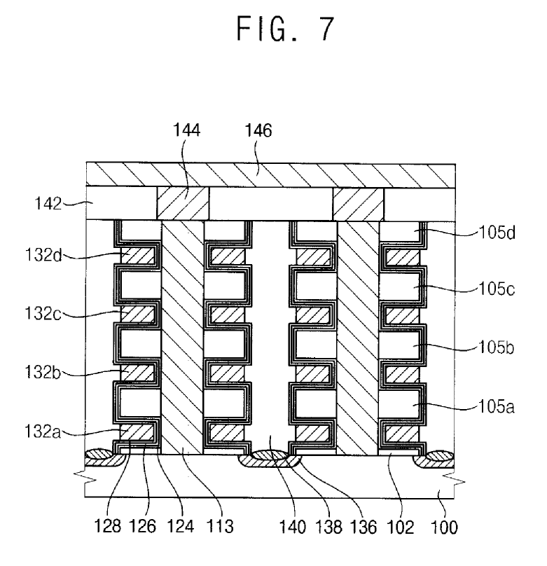

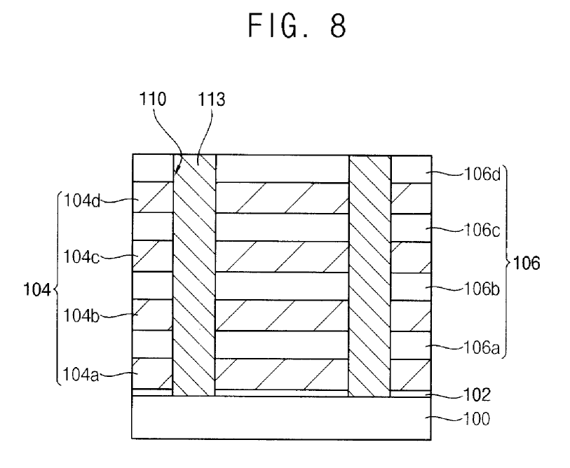

FIG. 7 is a schematic cross-sectional view illustrating a vertical semiconductor device in accordance with some exemplary embodiments of the inventive concept. FIG. 8 is a schematic cross-sectional view illustrating a method of manufacturing the vertical semiconductor device of FIG. 7, according to some exemplary embodiments of the inventive concept.

In some exemplary embodiments, the vertical semiconductor device illustrated in FIGS. 7 and 8 may have a structure substantially the same as that illustrated in FIGS. 1 and 2 except for a shape of the semiconductor pattern. As shown in FIGS. 7 and 8, in some exemplary embodiments, a semiconductor pattern 113 may have a solid cylindrical shape, i.e., a pillar shape, on the substrate 100.

The vertical semiconductor device in FIG. 7 may be manufactured by the following steps and processes.

In some exemplary embodiments, the sacrificial layers 104 and the insulating interlayers 106 may be formed alternately and sequentially on the substrate 100, and the first opening 110 may be formed by steps and processes substantially the same those described with reference to FIGS. 5A and 5B. In some exemplary embodiments, the sacrificial layers 104 may include boron and nitrogen.

Referring to FIG. 8, in some exemplary embodiments, a polysilicon layer may be formed to sufficiently fill the first opening 110. A portion of the polysilicon layer on the uppermost insulating interlayer 106d may be removed by a planarization process to form the semiconductor pattern 113 having the pillar shape.

Alternatively, in some exemplary embodiments, a polysilicon layer or an amorphous silicon layer may be formed in the first opening 110 and may be transformed into a single crystalline silicon layer by a phase transition by, for example, heat treatment or laser irradiation. After a planarization process, the semiconductor pattern 113 having a single crystalline structure may be formed.

Subsequently, steps and processes substantially the same as those illustrated in and described in detail with reference to FIGS. 5D to 5I may be performed to achieve the vertical semiconductor device in FIG. 7.

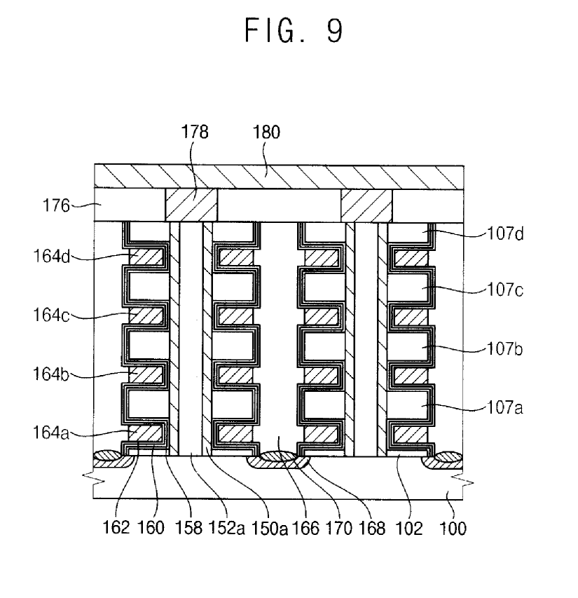

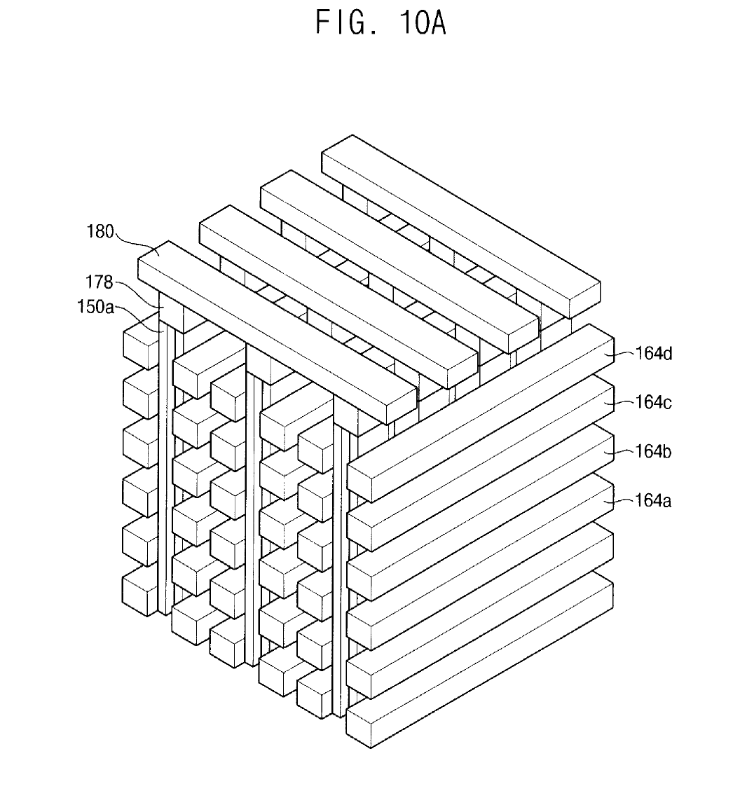

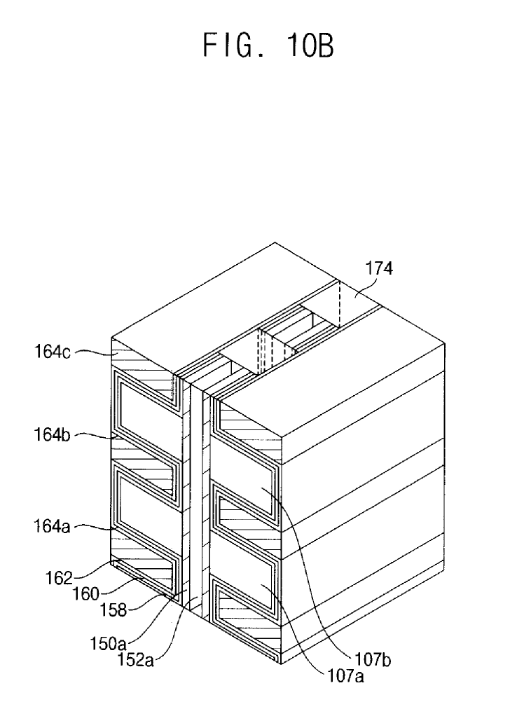

FIG. 9 is a schematic cross-sectional view illustrating a vertical semiconductor device in accordance with some exemplary embodiments of the inventive concept. FIG. 10A is a perspective view illustrating the vertical semiconductor device of FIG. 9, according to some exemplary embodiments. FIG. 10B is a perspective view illustrating a portion of the vertical semiconductor device of FIG. 9, according to some exemplary embodiments.

As shown in FIGS. 9, 10A and 10B, in some exemplary embodiments, a semiconductor pattern 150a may have, for example, a bar shape, e.g., a rectangular parallelepiped shape. A pair of semiconductor patterns 150a facing each other may be repeatedly arranged on the substrate 100 in the second direction. In some exemplary embodiments, a first insulation layer pattern 152a may be disposed in a gap between the facing semiconductor patterns 150a, and, in particular, between first lateral surfaces of the facing semiconductor patterns 150a.

A third insulation layer pattern 174 (see FIG. 10B) may be disposed in a gap between structures including the semiconductor patterns 150a and the first insulation layer pattern 152a that are disposed repeatedly in the first direction. The first and third insulation layer patterns 152a and 174 may include silicon oxide.

In some exemplary embodiments, transistors forming a string may be formed on a second lateral surface of the semiconductor pattern 150a opposite to the first lateral surface thereof contacting the first insulation layer pattern 152a. One semiconductor pattern 150a may serve as a channel region of the transistors. In some exemplary embodiments, the transistors may be connected in series to each other in the third direction.

Insulating interlayer patterns 107a, 107b, 107c and 107d may be disposed on the second lateral surface of the semiconductor pattern 150a to be spaced apart from each other in the third direction. The insulating interlayer patterns 107a, 107b, 107c and 107d may insulate control gate electrodes 164a, 164b, 164c and 164d from each other. The insulating interlayer patterns 107a, 107b, 107c and 107d may be formed protruding or extending from the second lateral surface of the semiconductor pattern 150a and may be arranged to be parallel to each other in each level of the vertically stacked structure. The insulating interlayer patterns 107a, 107b, 107c and 107d may have a linear shape extending in the first direction. Grooves exposing the second lateral surface of the semiconductor pattern 150a may be formed between the insulating interlayer patterns 107a, 107b, 107c and 107d, and gate structures may be formed in the grooves, respectively.

In some exemplary embodiments, outer edges of the insulating interlayer patterns 107a, 107b, 107c and 107d may have almost a right angle. That is, the insulating interlayer patterns 107a, 107b, 107c and 107d may have curved areas at the outer edges thereof at which top or bottom surfaces and outer sidewalls of the insulating interlayer patterns 107a, 107b, 107c and 107d meet each other. However, the curved areas may be very small in size. As a result, the top and bottom surfaces of the insulation interlayer patterns 105a, 105b, 105c and 105d may have planar areas that may be only slightly reduced because of the curved areas.

Additionally, in some exemplary embodiments, the insulating interlayer patterns 107a, 107b, 107c and 107d may have a thickness equal to or more than about 95% of an initial thickness of insulating interlayers. That is, the insulating interlayer patterns 107a, 107b, 107c and 107d may be prevented from being damaged or removed by subsequent processes by equal to or more than about 95% of the initial thickness of insulating interlayers.

In some exemplary embodiments, a tunnel insulation layer 158 may be formed on the second lateral surface of the semiconductor pattern 150a, which is exposed by the groove. The tunnel insulation layer 158 may be formed continuously on the second lateral surface of the semiconductor pattern 150a and the surfaces of the insulating interlayer patterns 107a, 107b, 107c and 107d.

In some exemplary embodiments, a charge trapping layer 160 may be formed on the tunnel insulation layer 158. In some exemplary embodiments, the charge trapping layer 160 may include, for example, silicon nitride or a metal oxide in which electrons may be trapped. The charge trapping layer 160 may be formed continuously throughout all the levels of the vertically stacked structure, or may be separated from each other according to the levels.

In some exemplary embodiments, a blocking layer 162 may be formed on the charge trapping layer 160. In some exemplary embodiments, the blocking layer 162 may include, for example, silicon oxide or a metal oxide. The metal oxide may include, for example, aluminum oxide.

Control gate electrodes 164a, 164b, 164c and 164d may be formed on the blocking layer 162 to fill the grooves and be separated from each other in each level. The control gate electrodes 164a, 164b, 164c and 164d may serve as word lines.

In some exemplary embodiments, the control gate electrodes 164a, 164b, 164c and 164d may have a linear shape extending in the first direction. The control gate electrodes 164a, 164b, 164c and 164d may extend facing the second lateral surface of the semiconductor pattern 150a. The control gate electrodes 164a, 164b, 164c and 164d may not be formed to surround an entire outer surface of the semiconductor pattern 150a in contrast to those illustrated in and described in detail with reference to FIG. 1. In some exemplary embodiments, the control gate electrodes 164a, 164b, 164c and 164d may include, for example, a metal or a metal nitride.

In some exemplary embodiments, a second insulation layer pattern 166 may be disposed in a gap between multi-stacked structures in which the control gate electrodes 164a, 164b, 164c and 164d and the insulating interlayer patterns 107a, 107b, 107c and 107d are alternately stacked. In some exemplary embodiments, the second insulation layer pattern 166 may extend in the first direction.

In some exemplary embodiments, an impurity region 168 may be formed at an upper portion the substrate 100 under the second insulation layer pattern 166. The impurity region 168 may serve as a CSL. For example, the impurity region 168 may be doped with n-type impurities. A metal silicide pattern 170 may be further formed on the impurity region 168.

In some exemplary embodiments, an upper insulating interlayer 176 may be formed on the semiconductor patterns 150a, the first, second and third insulation layer patterns 152a, 166 and 174 and the insulating interlayer pattern 107d. A bit line contact 178 may be formed through the upper insulating interlayer 176 to be electrically connected to the semiconductor pattern 150a. A bit line 180 may be formed on the upper insulating interlayer 176 to make contact with the bit line contact 178. Alternatively, the bit line 180 may make direct contact with the semiconductor pattern 150a without forming the upper insulating interlayer 176 and the bit line contact 178.

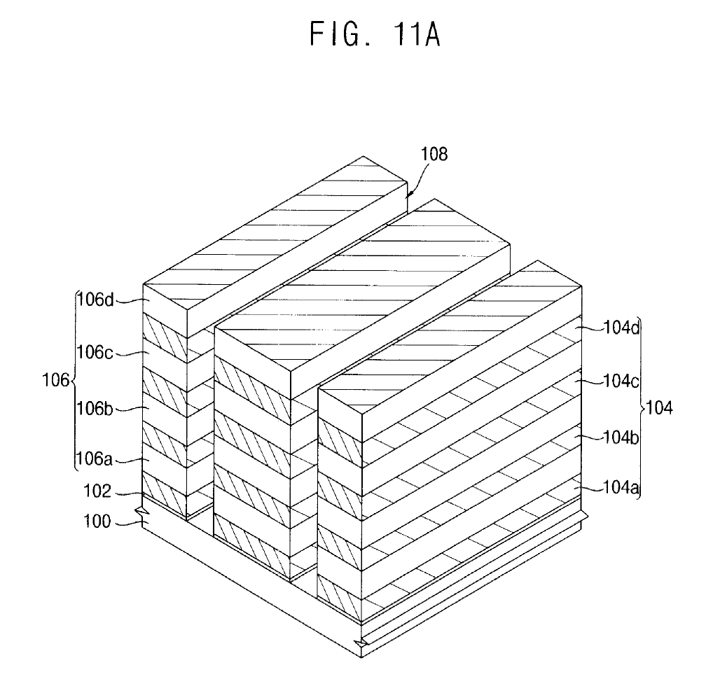

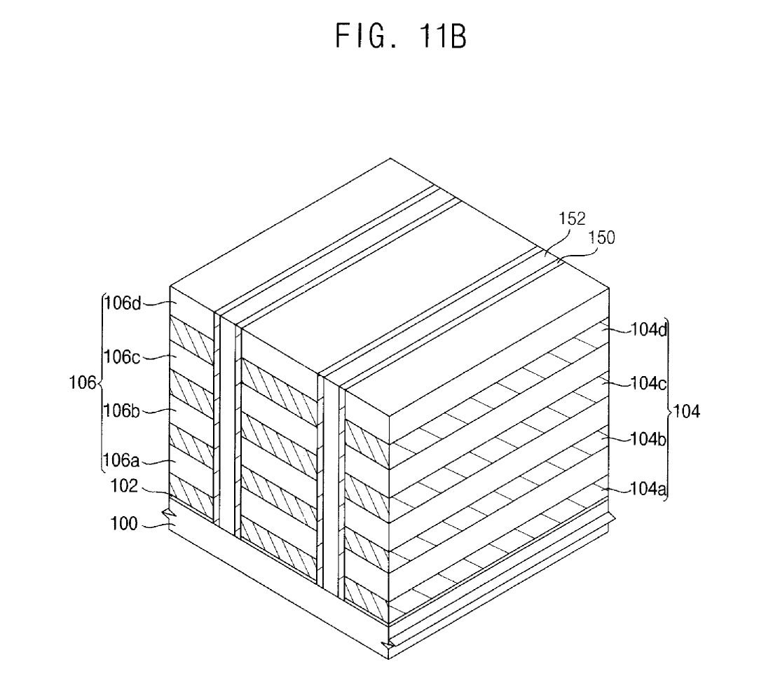

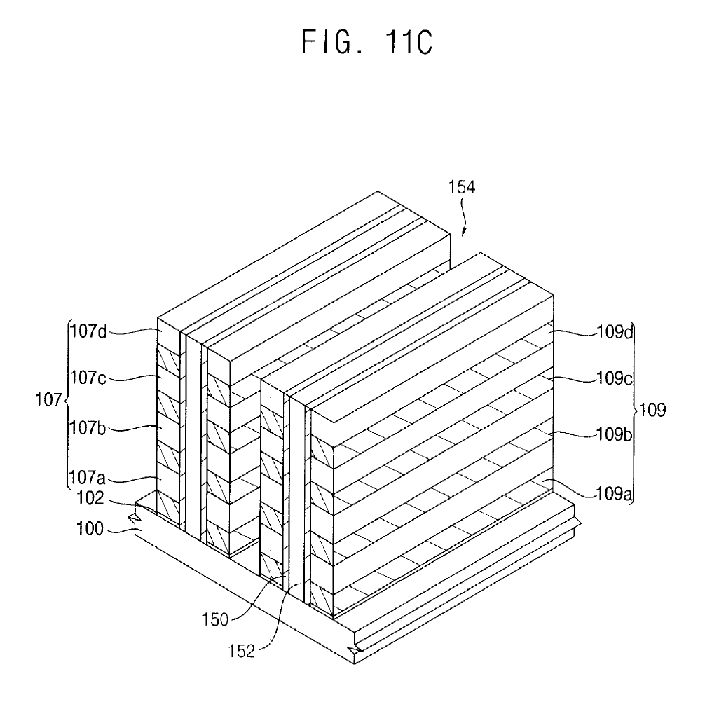

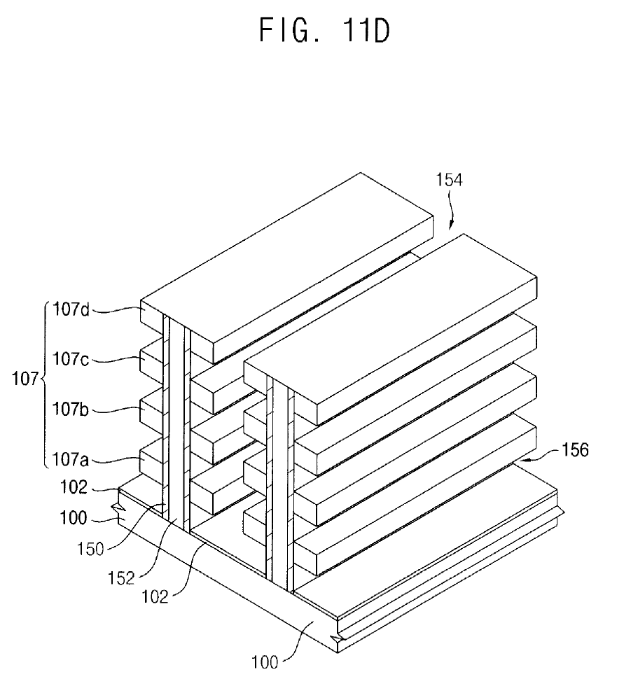

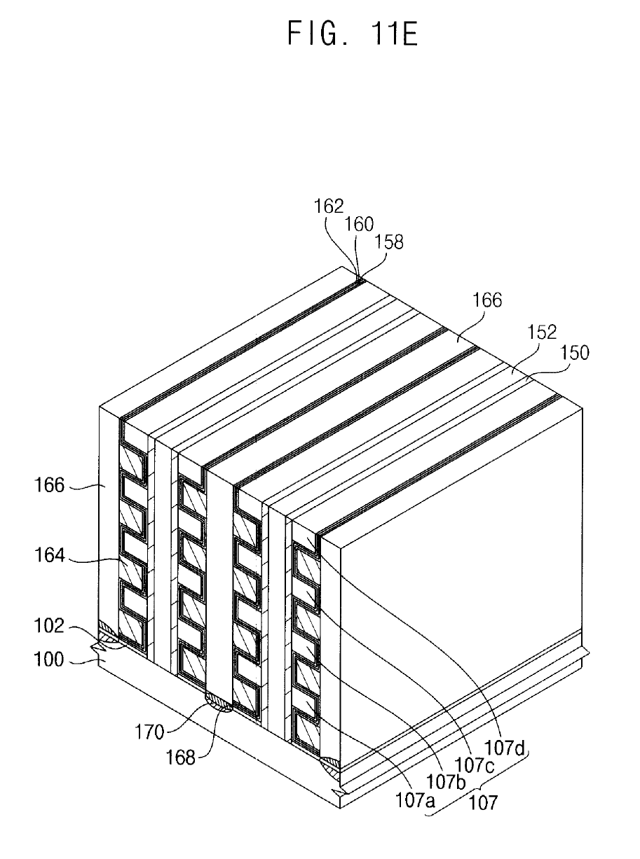

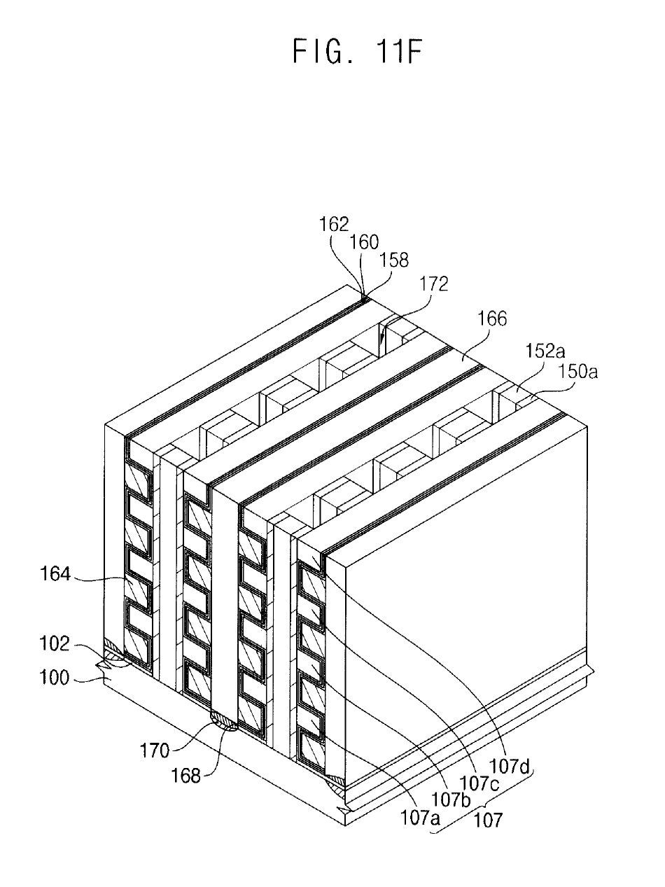

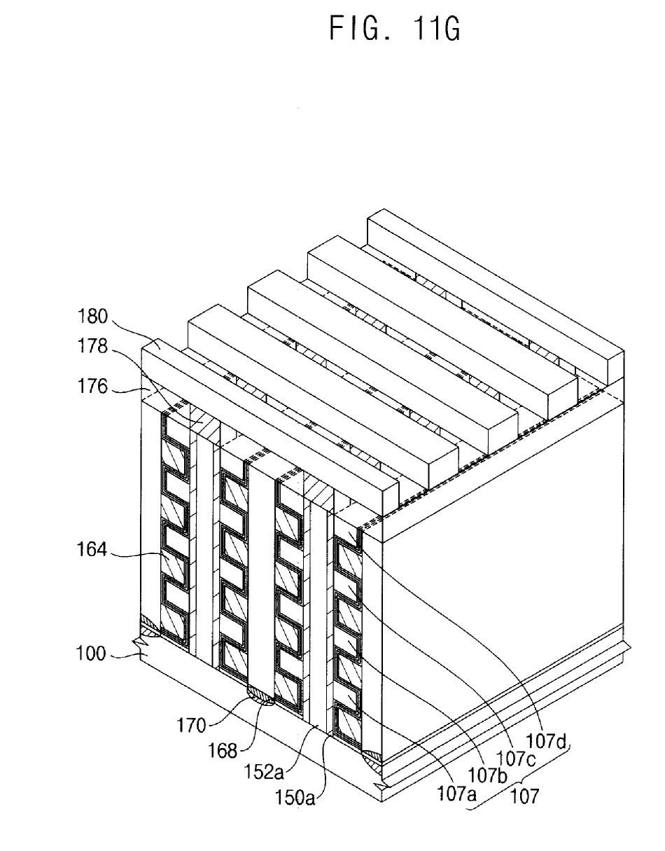

FIGS. 11A to 11G are schematic perspective views illustrating a method of manufacturing a vertical semiconductor device in accordance with exemplary embodiments of the inventive concept.

Hereinafter, the vertical semiconductor device will be described to include four transistors in one string. It will be understood that the detailed description contained herein applies to any number of transistors in a string.

Referring to FIG. 11A, in some exemplary embodiments, a pad insulation layer 102 may be formed on a substrate 100, and sacrificial layers 104 and insulating interlayers 106 may be repeatedly and alternately formed on the pad insulation layer 102 by processes substantially the same as those illustrated in and described in detail with reference to FIG. 4A. In some exemplary embodiments, the sacrificial layers 104 may be formed using a material that may include, for example, boron (B) and nitrogen (N).

Referring to FIG. 11A, an etching mask may be formed on an uppermost sacrificial layer 104d. The sacrificial layers 104, the insulating interlayers 106 and the pad insulation layer 102 may be sequentially and partially removed using the etching mask to form a first opening 108. In some exemplary embodiments, the first opening 108 may have a line shape extending in the first direction.

Referring to FIG. 11B, preliminary semiconductor patterns 150 may be formed on both sidewalls of the first opening 108. A preliminary first insulation pattern 152 may be formed to fill the first trench 108. Thus, in some exemplary embodiments, the two preliminary semiconductor patterns 150 may have a linear shape extending in the first direction in the first opening 108. In some exemplary embodiments, the preliminary semiconductor patterns 150 may be formed using, for example, single crystalline silicon or polysilicon.

In some exemplary embodiments, a polysilicon layer may be formed conformally on the sidewalls and a bottom of the first opening 108. The polysilicon layer formed on the bottom of the first opening 108 may be removed to form the preliminary semiconductor patterns 150 on the sidewalls of the first opening 108. An insulation layer may be formed on the uppermost insulating interlayer 106d to fill the first opening 108, and the insulation layer may be planarized until the uppermost insulating interlayer 106d is exposed to form a first preliminary insulation layer pattern 152.

In another exemplary embodiment, a polysilicon layer or an amorphous silicon layer may be formed on the sidewalls and the bottom of the first opening 108. The polysilicon or amorphous silicon layer is anisotropically etched to remain only on the sidewalls of the first opening 108. The polysilicon or amorphous silicon layer may be transformed into a single crystalline silicon layer by a phase-transition by, for example, a thermal treatment or laser irradiation. The first preliminary insulation layer pattern 152 may be formed by the steps and processes described in detail above.

Referring to 11C, in some exemplary embodiments, the sacrificial layers 104 and the insulating interlayers 106 between the first opening 108 may be partially etched to form a second opening 154. Specifically, in some exemplary embodiments, an etching mask may be formed on the uppermost insulating interlayer 106d. The insulating interlayers 106 and the sacrificial layers 104 may be sequentially and partially removed by an etching process using the etching mask to form the second opening 154. In some exemplary embodiments, the second opening may have a linear shape extending in the first direction. Accordingly, in some exemplary embodiments, sacrificial layer patterns 109 and insulating interlayer patterns 107 may be formed on an outer surface of the preliminary semiconductor pattern 150 to have a linear shape extending in the first direction.

Referring to FIG. 11D, in some exemplary embodiments, the sacrificial layer patterns 109 exposed by the second opening 154 may be removed to form grooves 156. The sacrificial layer patterns 109 may be removed by, for example, a wet etching process. In some exemplary embodiments, an etching solution for the wet etching processes may include, for example, sulfuric acid or phosphoric acid.

In some exemplary embodiments, the sacrificial layer patterns 109 may be removed by performing steps and processes substantially the same as those illustrated in and described in detail with reference to FIG. 5E. The insulating interlayer patterns 107 may be prevented from being damaged or removed so that the insulating interlayer patterns 107 may have almost constant thickness even after the wet etching process. In an exemplary embodiment, the insulating interlayer patterns 107 may have a thickness more than about 95% of an initial thickness of the insulating interlayers 106.

Referring to FIG. 11E, steps and processes substantially the same as those illustrated in and described in detail with reference to 5F and 5G may be performed. Specifically, in some exemplary embodiments, a tunnel insulation layer 158, a charge trapping layer 160 and a blocking layer 162 may be formed sequentially on outer sidewalls of the preliminary semiconductor pattern 150 exposed by the grooves 156 and the insulating interlayer patterns 107. In some exemplary embodiments, a conductive layer may be formed on the blocking layer 162 to sufficiently fill the grooves 156.

A portion of the conductive layer formed in the second opening 154 may be removed. Portions of the tunnel insulation layer 158, the charge trapping layer 160 and the blocking layer 162 formed on a bottom of the second opening 154 may be also removed to form a third opening (not shown) through which the substrate 100 may be exposed. The conductive layer, the tunnel insulation layer 158, the charge trapping layer 160 and the blocking layer 162 formed in the second opening 154 may be removed by the wet etching processes, which, in some exemplary embodiments, are substantially the same as those illustrated in and described in detail with reference to FIG. 5H.

By performing the steps and processes, control gate electrodes 164 may be formed between the insulating interlayer patterns 107. In some exemplary embodiments, the control gate electrode in each level may have a linear shape extending in the first direction. In some exemplary embodiments, the control gate electrodes in different levels may be insulated from each other by the insulating interlayer patterns 107.

Next, an upper portion of the substrate 100 exposed by the third opening may be doped with impurities, e.g., n-type impurities, to form an impurity region 168, which in some exemplary embodiments, serves as a CSL. In some exemplary embodiments, a metal silicide pattern 170 may be further formed on the impurity region 168 in order to reduce resistance of the CSL.

In some exemplary embodiments, an insulation layer may be formed on the substrate 100 to fill the third opening, and then the insulation layer may be planarized until the uppermost insulating interlayer pattern 107d is exposed to form a second insulation layer pattern 166 in the third opening.

Referring to FIG. 11F, a mask pattern may be formed on the structure illustrated in FIG. 11E to extend in the second direction. The preliminary semiconductor pattern 150 and the first preliminary insulation layer pattern 152 may be partially removed using the mask pattern as an etching mask to form openings 172. Accordingly, in some exemplary embodiments, a semiconductor pattern 150a and a first insulation layer pattern 152a may be formed to have a bar shape, e.g., a rectangular parallelepiped shape.

Referring to FIG. 11G, third insulation layer patterns may be formed to fill the openings 172.

In some exemplary embodiments, an upper insulating interlayer 176 may be formed on the semiconductor patterns 150a, the first, second and third insulation layer patterns 152a, 166 and 174 and the insulating interlayer pattern 107d. In some exemplary embodiments, a bit line contact 178 may be formed through the upper insulating interlayer 176 to be electrically connected to the semiconductor pattern 150a. In some exemplary embodiments, a bit line 180 may be formed on the upper insulating interlayer 176 to make contact with the bit line contact 178.

As described above, in accordance with exemplary embodiments, defects introduced by a process for manufacturing a vertical semiconductor device due to the stress of the sacrificial layers 104 is reduced. Additionally, the insulating interlayers 106 may be formed to have an improved surface profile so that the vertical semiconductor device has high reliability.

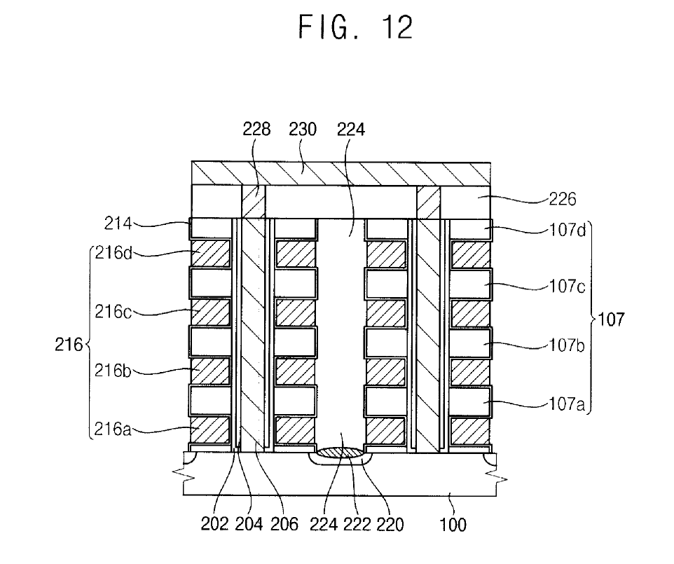

FIG. 12 is a schematic cross-sectional view illustrating a vertical semiconductor device in accordance with some exemplary embodiments of the inventive concept.

The vertical semiconductor device in FIG. 12 may have a structure substantially the same as that illustrated in and described in detail with reference to FIGS. 1 and 2, except for a shape of a tunnel insulation layer, a charge trapping layer and a blocking layer.

Referring to FIG. 12, a semiconductor pattern 206 may be disposed on the substrate 100 having a solid cylindrical, i.e., a pillar, shape. A top surface of the semiconductor pattern 206 may have a circular shape.

In some exemplary embodiments, a tunnel insulation layer 204 may be formed to at least partially surround an outer surface of the semiconductor pattern 206. A charge trapping layer 202 may be formed on the tunnel insulation layer 204.

Insulating interlayer patterns 107 may be disposed protruding or extending from the charge trapping layer 202. The insulating interlayer patterns 107 may extend in the first direction in each level of the vertically stacked structure and may be spaced apart from each other in the third direction. Grooves may be defined by spaces between the insulating interlayer patterns 107. In some exemplary embodiments, the insulating interlayer patterns 107 may have a thickness equal to or more than 95% of an initial thickness of insulation interlayers.

A blocking layer 214 may be formed on the charge trapping layer 202 exposed by the grooves and the insulating interlayer patterns 107.

Control gate electrodes 216 may be formed on the blocking layer 214 in each level to fill the grooves. In some exemplary embodiments, the control gate electrodes 216 may have a linear shape extending in the first direction and at least partially surrounding the semiconductor pattern 206.

A first insulation layer pattern 224 may be disposed in a gap between multiple adjacent multi-stacked structures including the control gate electrodes 216 and the insulating interlayer patterns 107. In some exemplary embodiments, the first insulation layer pattern 224 may have a linear shape extending in the first direction.

An impurity region 220 may be formed at an upper portion of the substrate 100 under the first insulation pattern 224. In some exemplary embodiments, the impurity region 220 may be doped with, for example, n-type impurities. In some exemplary embodiments, a metal silicide pattern 222 may be further formed on the impurity region 220.

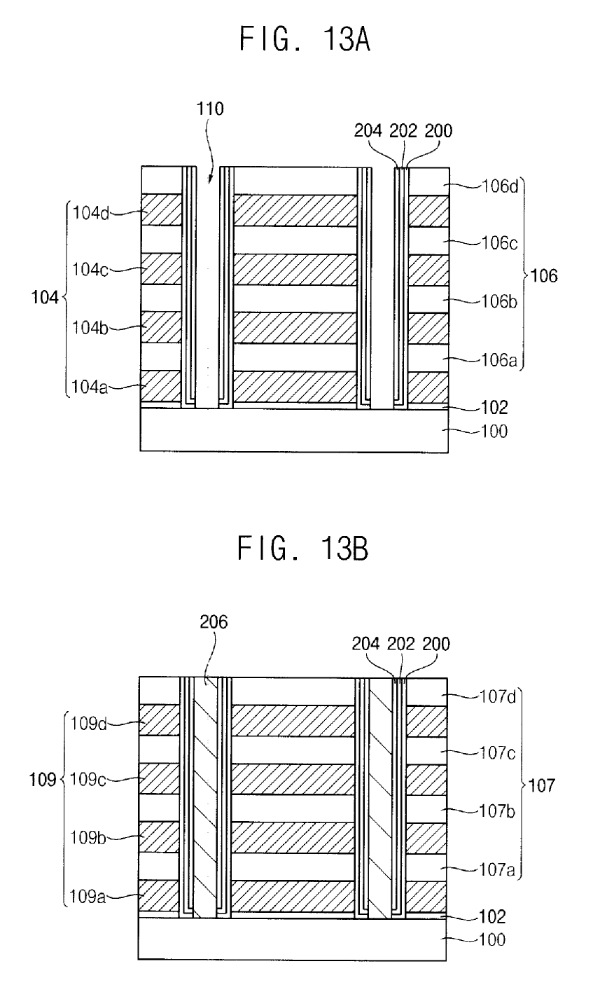

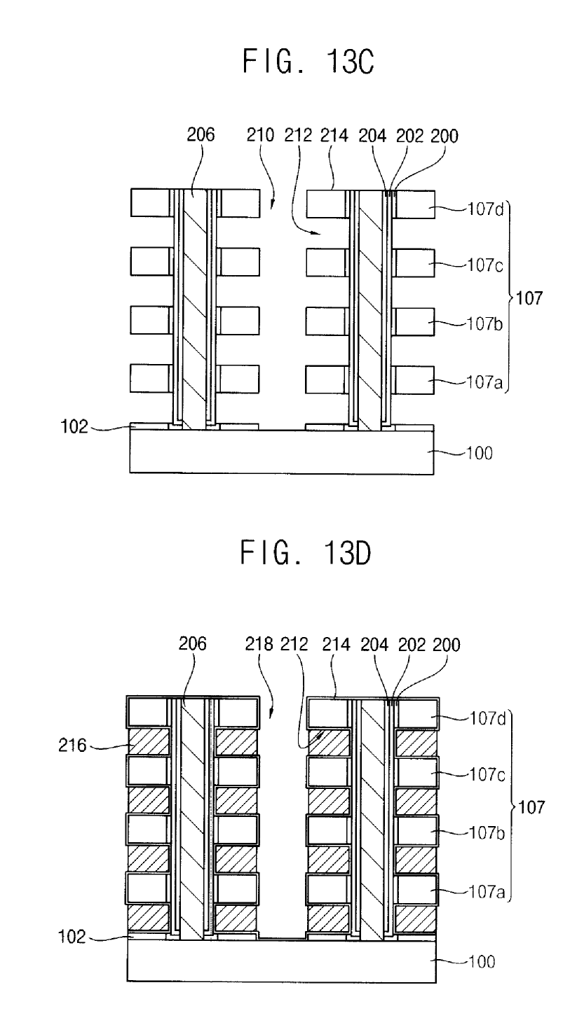

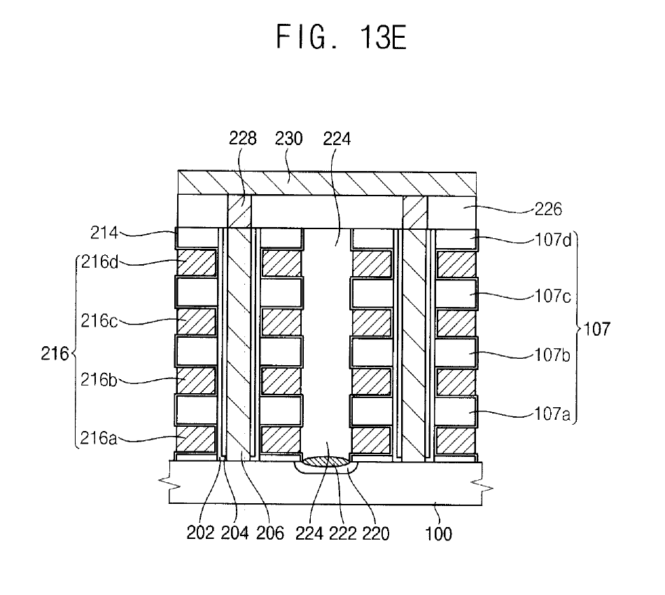

FIGS. 13A to 13E are schematic cross-sectional views illustrating a method of manufacturing the vertical semiconductor device of FIG. 12, according to some exemplary embodiments of the inventive concept.

Referring to FIG. 13A, in some exemplary embodiments, sacrificial layers 104 and insulating interlayers 106 may be formed, and then a first opening 110 may be formed by performing steps and processes substantially the same as those illustrated in and described in detail with reference to FIGS. 5A and 5B. In some exemplary embodiments, the sacrificial layers 104 may be formed using boron and nitrogen.

A preliminary blocking layer may be formed on a sidewall and a bottom of the first opening 110. A preliminary charge trapping layer and a preliminary tunnel insulation layer may be sequentially formed on the preliminary blocking layer. The preliminary blocking layer, the preliminary charge trapping layer and the preliminary tunnel insulation layer formed on the bottom of the first opening 110 may be selectively removed to form a blocking layer 200, a charge trapping layer 202 and a tunnel insulation layer 204, which are formed sequentially on the sidewall of the first opening 110. A top surface of the substrate 100 may be exposed by the first opening 110.

Referring to FIG. 13B, in some exemplary embodiments, a semiconductor pattern 206 may be formed to fill the first opening 110. The semiconductor pattern 206 may be formed to make direct contact with the tunnel insulation layer 204.

In some exemplary embodiments, a polysilicon layer may be formed to completely fill the first opening 110. The polysilicon layer may be planarized until an uppermost insulating interlayer pattern 107d is exposed to form the semiconductor pattern 206.

In some exemplary embodiments, a polysilicon layer or an amorphous silicon layer may be formed in the first opening 110, and then the polysilicon layer or the amorphous silicon layer may be transformed into a single crystalline silicon layer by a phase-transition using, for example, a heat treatment or laser irradiation. A planarization process may be performed on the single crystalline silicon layer to form the semiconductor pattern 206.

Referring to FIG. 13C, the sacrificial layers 104 and the insulating interlayers 106 between the semiconductor patterns 206 may be partially etched to form a second opening 210. The second opening 210 may be formed to extend in the first direction. By forming the second opening 210, sacrificial layer patterns 109 and insulating interlayer patterns 107 may be formed.

The sacrificial layer patterns 109 exposed by the second opening 210 may be removed to form grooves 212. In some exemplary embodiments, the blocking layer 200 exposed by the grooves 212 may also be removed together with the sacrificial layer patterns 109, because the blocking layer 200 may have defects after deposition thereof.

In some exemplary embodiments, the sacrificial layer patterns 109 and the blocking layer 200 may be selectively removed by a wet etching process using, for example, sulfuric acid or phosphoric acid as an etching solution so that the insulating interlayer patterns 107 may be arranged on the sidewall of the semiconductor pattern 206 to be spaced apart from each other with a constant distance.

In some exemplary embodiments, outer edges of the insulating interlayer patters 107 formed may only slightly be removed during the wet etching process, such that the curved areas may be relatively small, and the outer edges of the insulating interlayer patterns 107 may have almost a right angle. Additionally, the insulating interlayer patterns 107 may have almost constant thickness even after the wet etching process. In some exemplary embodiments, the insulating interlayer patterns 107 may have a thickness more than about 95% of an initial thickness of the insulating interlayers 106.

Referring to FIG. 13D, in some exemplary embodiments, a blocking layer 214 may be formed on the insulating interlayer patterns 107 and the charge trapping layer 202 exposed by the grooves. In some exemplary embodiments, the blocking layer 214 may be formed using, for example, silicon oxide or metal oxide such as aluminum oxide.

In such exemplary embodiments, the tunnel insulation layer 204 and the charge trapping layer 202 may be formed to completely surround the outer surface of the semiconductor pattern 206. However, the blocking layer 214 may have a different shape from that of the tunnel insulation layer 204 and the charge trapping layer 202. Specifically, the tunnel insulation layer 201 and the charge trapping layer 202 may not be formed on an inner surface of the grooves 212. Accordingly, a width of the grooves 212 may not be reduced by the tunnel insulation layer 201 and the charge trapping layer 202. As a result, control gate electrodes 216 having a sufficient thickness may be formed in the grooves 212, such that resistance of the control gate electrodes 216 and an entire height of a semiconductor device may be decreased.

In some exemplary embodiments, a conductive layer may be formed on the blocking layer 214 to sufficiently fill the grooves 212 by steps and processes substantially the same as those illustrated in and described in detail with reference to FIG. 5G.

A portion of the conductive layer formed in the second opening 210 may be removed. In some exemplary embodiments, a portion of the blocking layer 214 formed on the bottom of the second opening 210 may also be removed to form a third opening 218 that exposes the substrate 100. In some exemplary embodiments, the conductive layer and the blocking layer 214 may be selectively removed by a wet etching process.

Referring to FIG. 13E, in some exemplary embodiments, an upper portion of the substrate 100 exposed by the third opening 218 may be doped with impurities, e.g., n-type impurities, to form an impurity region 220 serving as a CSL line.

In some exemplary embodiments, an insulation layer may be formed on the substrate 100 to fill the third opening 218, and then may be planarized until the uppermost insulating interlayer pattern 107d is exposed, to form a first insulation layer pattern 224. In some exemplary embodiments, an upper insulating interlayer 226, a bit line contact 228 and a bit line 230 may be formed by steps and processes substantially the same as those illustrated in and described in detail with reference to FIG. 5I. In some exemplary embodiments, the bit line 230 may have a linear shape extending in the second direction and may be electrically connected to the semiconductor patterns 206 via the bit line contact 228.

Evaluation on Wet Etching Rates

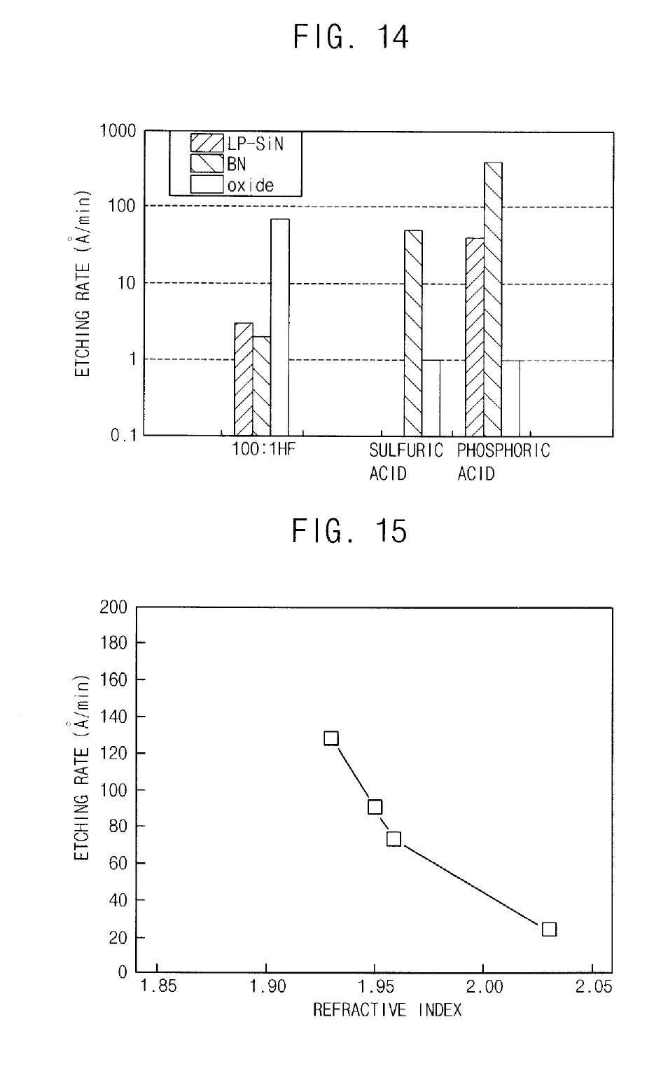

A BN layer, a SiN layer and a silicon oxide layer were formed on a substrate. The SiN layer was formed by a low pressure chemical vapor deposition (LPCVD) process. Etching rates of the layers were measured with respect to different etching solutions. The result is shown in FIG. 14.

Referring to FIG. 14, the BN layer had an etching selectivity with respect to the silicon oxide layer higher than that of the SiN layer, when phosphoric acid was used as the etching solution. When sulfuric acid was used as the etching solution, the BN layer also had a high etching selectivity with respect to the silicon oxide layer. When hydrofluoric acid having a dilution ratio of about 1:100 was used, the silicon oxide layer had the highest etching rate among the three layers.

Evaluation on Stress

Stress values for layers in following Examples and Comparative Examples were measured, and the results are tabulated in Table 1.

TABLE 1

| | | Stress Values | |
|---|---|---|---|
| | | At | After performing a heat |
| | Deposited Layer | deposition | treatment at 600° C. |
| Exemplary 1 | High temperature | 0.1 Gpa | No change |
| | LPCVD, SiBN layer | | |
| Exemplary 2 | High temperature | −0.5 Gpa | No change |
| | LPCVD, BN layer | | |
| Comparative | Low temperature, | 0.1 Gpa | 1.2 Gpa |
| Exemplary 1 | PECVD, SiN layer | | |
| Comparative | High temperature | 1.1 Gpa | No change |
| Exemplary 2 | LPCVD, SiN layer | | |

As shown in Table 1, the SiBN layer and the BN layer had stresses and stress change values lower than those of the SiN layer.

FIG. 15 is a graph showing etching rates of SiBN layer.

Referring to FIG. 15, as an amount of boron included in a SiBN layer increased, a refractive index thereof was decreased. Thus, a lower refractive index may indicate that the SiBN layer includes more boron. Accordingly, it is apparent that an etching rate of the SiBN layer may be increased as the amount of boron therein increases.

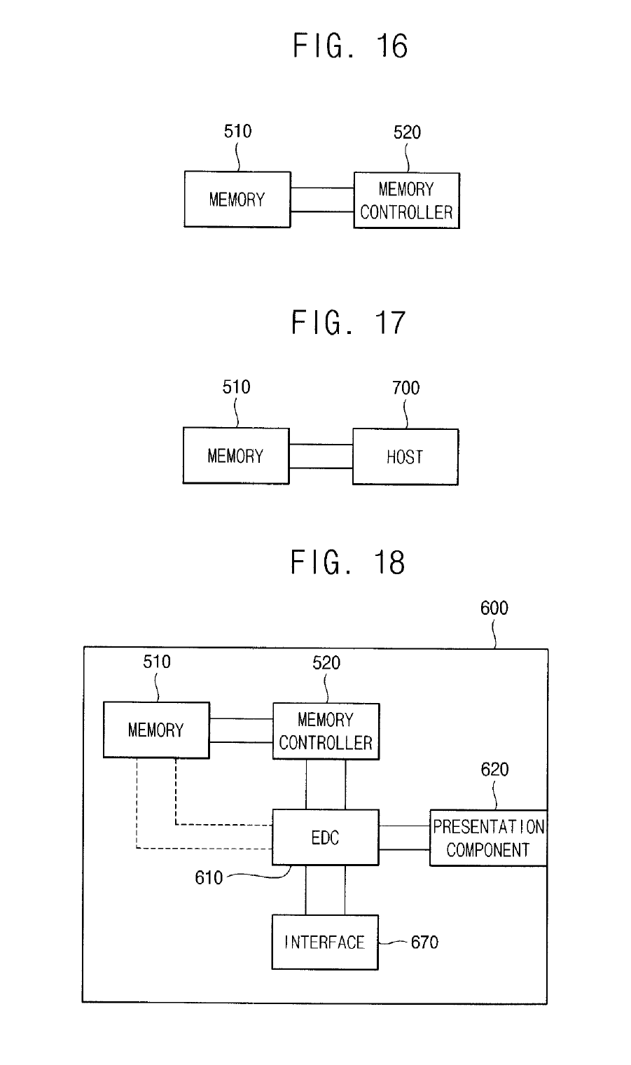

FIG. 16 contains a schematic block diagram which illustrates a memory card including the vertical semiconductor device in accordance with exemplary embodiments of the inventive concept.

Referring to FIG. 16, the memory card may include a memory 510 connected to a memory controller 520. The memory 510 may include any of the vertical semiconductor devices according to the various exemplary embodiments described in detail herein. The memory controller 520 may supply input signals for controlling the operation of the memory 510.

FIG. 17 contains a schematic block diagram which illustrates a system including the vertical semiconductor device in accordance with exemplary embodiments of the inventive concept.

The system may include a memory 510 connected to a host 700. The memory 510 may include any of the vertical semiconductor devices according to the various exemplary embodiments described in detail herein.

FIG. 18 contains a schematic block diagram which illustrates a portable device including the vertical semiconductor device in accordance with exemplary embodiments of the inventive concept. The portable device 600 may be an MP3 player, video player, combination video and audio player, etc. As illustrated, the portable device 600 may include the memory 510 and memory controller 520. The memory 510 may include any of the vertical semiconductor devices according to the various exemplary embodiments described in detail herein. The portable device 600 may also include an encoder/decoder EDC 610, a presentation component 620 and an interface 670. Data (video, audio, etc.) is input to and output from the memory 510 via the memory controller 520 by the EDC 610.

The foregoing is descriptive of exemplary embodiments and is not to be construed as limiting thereof. Although some exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims.

1. A method of manufacturing a vertical semiconductor device, comprising:
forming a plurality of sacrificial layers and a plurality of insulating interlayers on a substrate, the sacrificial layers including boron (B) and nitrogen (N) and having an etching selectivity with respect to the insulating interlayers, the plurality of sacrificial layers and the plurality of insulating interlayers being repeatedly and alternately stacked on the substrate;
forming semiconductor patterns on the substrate, the semiconductor patterns being formed through the sacrificial layers and the insulating interlayers;
partially removing the sacrificial layers and the insulating interlayers between the semiconductor patterns to form sacrificial layer patterns and insulating interlayer patterns on sidewalls of the semiconductor patterns;
removing the sacrificial layer patterns to form grooves between the insulating interlayer patterns, the grooves exposing portions of the sidewalls of the semiconductor patterns; and
forming a gate structure in each of the grooves.

2. The method of claim 1, wherein the sacrificial layers include at least one material selected from the group consisting of BN, c-BN, SiBN, SiBCN, BN containing oxygen, and SiBN containing oxygen

3. The method of claim 1, wherein the sacrificial layers are formed using BCl3 and NH3 as a source gas under an atmosphere of Ar.

4. The method of claim 3, wherein an etching rate of the sacrificial layers is controlled by adjusting a flow rate of BCl3 in the source gas.

5. The method of claim 3, wherein the source gas for forming the sacrificial layers further includes a silicon source gas.

6. The method of claim 3, wherein the source gas for forming the sacrificial layers further includes a carbon or an oxygen source gas.

7. The method of claim 1, wherein the insulating interlayers include at least one material selected from the group consisting of silicon oxide, SiOC and SiOF.

8. The method of claim 1, wherein forming the gate structure includes:
sequentially forming a tunnel insulation layer, a charge trapping layer and a blocking layer on the exposed portions of the sidewalls of the semiconductor patterns and surfaces of the insulating interlayer patterns;
forming a conductive layer on the blocking layer to fill the grooves; and
partially removing the conductive layer to form gate electrodes in the grooves.

9. The method of claim 1, wherein the sacrificial layer patterns are removed using sulfuric acid or phosphoric acid.

10. The method of claim 1, wherein forming the semiconductor patterns includes:
partially removing the sacrificial layers and the insulating interlayers to form an opening through the sacrificial layers and the insulating interlayers, the opening exposing a top surface of the substrate;
forming a semiconductor layer on the exposed top surface of the substrate to fill the opening; and
forming a semiconductor pattern in the opening by planarizing an upper portion of the semiconductor layer.

11. The method of claim 1, wherein forming the semiconductor patterns includes:
partially removing the sacrificial layers and the insulating interlayers to form an opening through the sacrificial layers and the insulating interlayers, the opening exposing a top surface of the substrate;
forming a semiconductor layer on the exposed top surface of the substrate and a sidewall of the opening;
forming a filling layer on the semiconductor layer to fill the opening; and
forming a semiconductor pattern and a filling layer pattern by planarizing upper portions of the filling layer and the semiconductor layer.

12-16. (canceled)

17. A method of manufacturing a vertical semiconductor device, comprising:
alternately stacking a plurality of sacrificial layers and a plurality of insulating interlayers on a substrate, the plurality of sacrificial layers including boron (B) and nitrogen (N) and having an etching selectivity with respect to the insulating interlayers, the plurality of sacrificial layers being formed using at least one of BCl3 and NH3 as a source gas;
forming semiconductor patterns on the substrate, the semiconductor patterns being formed through the sacrificial layers and the insulating interlayers;
at least partially removing the sacrificial layers and the insulating interlayers between the semiconductor patterns to form sacrificial layer patterns and insulating interlayer patterns on sidewalls of the semiconductor patterns;
removing the plurality of sacrificial layer patterns to form a respective plurality of grooves between the insulating interlayer patterns, the plurality of grooves exposing portions of the sidewalls of the semiconductor patterns; and
forming a plurality of gate structures in the plurality of grooves, respectively, wherein forming the plurality of gate structures comprises:
sequentially forming a tunnel insulation layer, a charge trapping layer and a blocking layer on the exposed portions of the sidewalls of the semiconductor patterns and surfaces of the insulating interlayer patterns,
forming a conductive layer on the blocking layer to fill the grooves, and
at least partially removing the conductive layer to form gate electrodes in the grooves.

18. The method of claim 17, wherein the sacrificial layers are formed in an atmosphere comprising Ar.

19. The method of claim 17, wherein the sacrificial layers comprise at least one of BN, c-BN, SiBN, SiBCN, BN containing oxygen, and SiBN containing oxygen.

20. The method of claim 17, further comprising adjusting a flow rate of BCl3 in the source gas to control an etching rate of the plurality of sacrificial layers.
